(19) United States
(12) Patent Application Publication
(10) Pub. No.: US 2024/0242092 A1
(43) Pub. Date: Jul. 18, 2024

(54) PLACEMENT PATH OPTIMIZATION METHOD OF SURFACE MOUNT MACHINE BASED ON ROW-COLUMN GROUPING GENETIC ALGORITHM

(71) Applicant: Ningbo Yik-Tong Intelligent Technology Co., LTD, Nngbo (CN)

(72) Inventors: Huijun Gao, Ningbo (CN); Zhengkai Li, Ningbo (CN); Hao Sun, Ningbo (CN); Xinghu Yu, Ningbo (CN)

(21) Appl. No.: 18/378,072

(22) Filed: Oct. 9, 2023

(30) Foreign Application Priority Data
Jan. 17, 2023 (CN) 202310117707X

(51) Int. Cl. G06N 3/126

(52) U.S. Cl. CPC G06N 3/126

(57) ABSTRACT

The present disclosure relates to placement path optimization methods of a surface mount machine and in particular to a placement path optimization method of a surface mount machine based on row-column grouping genetic algorithm. The method includes the following steps: 1. obtaining production parameters and data; 2. grouping placement points into matrix rows based on rows; 3. encoding chromosomes to generate a chromosome population; 4. decoding chromosomes to obtain column grouping results for placement points and calculating placement path lengths; 5. setting parameters and loop conditions for the genetic algorithm; 6. updating optimization results based on crossover operators; 7. updating optimization results based on mutation operators; outputting the optimal placement path. This invention falls within the realm of electrical technology and electrical engineering.

### CROSS-REFERENCE TO RELATED APPLICATION

This application claims priority from the Chinese patent application 202310117707X filed Jan. 17, 2023, the content of which is incorporated herein in the entirety by reference.

### TECHNICAL FIELD

The present disclosure relates to electric appliance technologies and the electrical engineering field, and in particular to a placement path optimization method of a surface mount machine.

### BACKGROUND

In modern production and daily life, people use a large number of electric devices, and the functions of these devices are implemented depending on various electronic components and chips provided thereon and circuit boards with electric connections. In order to assemble a circuit board with full functions, it is necessary to use a surface mount technology with a surface mount machine as a core device. The surface mount machine is capable of accurately and swiftly picking electronic components, electronic devices, or chips and placing them onto their corresponding placement points on the circuit board's surface. For ease of description, the “electronic component, electronic device, and chip” are collectively referred to as “component”, and the “pick and place” are referred to as “PAP”.

The current mainstream surface mount machines are all constructed on the XYZ three-axis movement platform shown in FIG. 2. When the mount task is performed, the gantry type surface mount carrier shown in FIG. 2 is most often used. In the gantry type surface mount carrier, a plurality of suction heads capable of sucking and blowing air are mounted equidistantly along X axis direction; each suck rod is driven to move up and down along a Z direction by a motor inside the surface mount carrier; and the surface mount carrier is driven by a horizontal movement track and a fixed track to move along X and Y directions in a horizontal plane. With the above movement mechanism, picking, movement, and mounting for the components can be completed. Before the pick-mount process is started, when the circuit board is conveyed to a proper place by a conveying belt, the circuit board is pressed and fixed. During the pick-mount process, a component feeder fixedly mounted on a base of the component feeder will automatically replenish the components, and the components supplied to be in the proper position will appear at a pick point at the front of the component feeder and wait for being picked.

The pick-mount process of the surface mount machine is shown in FIG. 3. Since the number of the suction heads is limited to be much less than the number of the placement points, the surface mount carrier needs to complete the mounting of one complete circuit board through several pick and place periods (PAP cycles). One pick-mount process in one PAP cycle can be summarized as follows: the surface mount carrier firstly moves to the base of the component feeder; the suction heads of the surface mount carrier move to the corresponding pick point to pick up an component respectively; when all suction heads pick their respective components, the surface mount carrier moves to the circuit board; each suction head on the surface mount carrier moves to the corresponding placement point for mounting of the corresponding component. After all suction heads complete the mounting of the components; the pick-mount process of the next PAP cycle is started.

From the angle of signal integrity and aesthetics and the like, the array component layout shown in FIG. 2 may be used for designing a large number of circuit boards. On a circuit board provided with an LED lamp, it is especially usual practice to dispose the LED lamp, a resistor, a capacitor, and the like as an component array. A direction parallel to the X axis is defined as row direction and a direction parallel to the Y axis is defined as column direction. The components with Y coordinates approximately equally distributed along the X direction are regarded as one row, which is called a “dot array row”, whereas the components with X coordinates approximately equally distributed along the Y direction are regarded as one column. The “dot array rows” with an equal number of columns and the X coordinates of each component column being equal are referred to as “same type of dot array rows”.

The pick-mount process of the surface mount machine is optimized to greatly shorten the surface mount time. One important target in the pick-mount process is to minimize the placement path length. In the pick-mount process, the path that each suction head moves to complete component mounting sequentially is called the placement path. The invention with patent number 202010387801.3 provides a general placement path optimization method. But, when the optimization problem of the pick-mount process of the circuit board containing component array is processed by this method, the obtained placement path is far from the optimal solution.

The major defects under investigation are as follows: the existing placement path optimization algorithm lacks a special design for the component array and is unable to ensure the placement points in the component array are mounted row by row and thus undermines the regularity of the array component layout. Thus, the path length of each period can not be collaboratively optimized. Since the search space is large, the search capability for the optimal solution is poor and the search process is time-consuming.

### SUMMARY

The object of the present disclosure is to solve the problems: the existing placement path optimization algorithm lacks a special design for the component array and is unable to ensure the placement points in the component array are mounted row by row and thus undermines the regularity of the array component layout; and thus, the path length of each period can not be collaboratively optimized; furthermore, due to the extensive search space, there are problems such as poor search capabilities for optimal solutions and lengthy search processes. In view of the above, there is provided a placement path optimization method of a surface mount machine based on a row-column grouping genetic algorithm.

The specific process of performing the placement path optimization method of the surface mount machine based on the row-column grouping genetic algorithm comprises the following steps:
at step 1, obtaining a surface mount machine parameter and circuit board production data;
at step 2, grouping placement points in a row to obtain dot array rows;
at step 3, encoding the row grouping results of the placement points to generate a chromosome population;
at step 4, decoding the chromosomes to obtain column grouping results of the placement points within the dot array rows, converting the column grouping results into placement path optimization results, calculating the placement path lengths, and outputting them;
at step 5, setting parameters and loop conditions for the genetic algorithm;
at step 6, based on the crossover operator, operating each chromosome and updating the placement path optimization result by comparison and selection;
at step 7, based on the mutation operator, operating each chromosome and updating the placement path optimization result by comparison and selection;
at step 8, outputting the optimal placement path optimization result.

The present disclosure has the following beneficial effects.

For the circuit board layout type expressed as an component array, the present disclosure provides a row-by-row mounting manner as shown in FIG. 1, namely, the mounting of placement points in a same dot array row is preferentially completed in a same PAP cycle. The mounting of other nearby dot array rows is not performed until the placement points in the row are all mounted. The advantages of the “row-by-row mounting manner” will be described below. Since the suction heads in the gantry type surface mount carrier are arranged along the row direction, namely, the Y coordinates of all the suction heads at any time are always equal, for a same type of “dot array rows”, the proof-of-contradiction method can be adopted to prove the following: in one component array, if the optimal placement path can be obtained by accessing other dot array rows, it is sure that there is a placement point p₁ with the same X coordinate as the optimal placement point in the current dot array row; further, since the placement points located in a same dot array row are closer to each other in the Y direction, the path for accessing the placement point p₁ is surely better. For different types of “dot array rows”, nearby row-by-row mounting is adopted to avoid large-span movement along the Y direction in the subsequent mounting process, so as to obtain a globally optimal solution with higher probability.

The present disclosure provides a placement path optimization method of a surface mount machine based on a row-column grouping genetic algorithm, in which, for a circuit board with an component array, a row-by-row mounting manner for quickly determining a placement sequence is proposed and a method of row and column grouping for placement points is provided. Without loss of the optimal solution, the search space is greatly narrowed, and a genetic algorithm coding and decoding method matching the row and column grouping method are provided. Thus, specially-designed genetic operation is performed on each chromosome stage by stage, so as to quickly and stably obtain a global approximate optimal solution and finally greatly shorten the placement path and increase the surface mount production efficiency. Experiments show that the method provided by the present disclosure can significantly increase the production efficiency of the surface mount machine, with the computation efficiency increased by 12.1 folds over the previous method, thus increasing the maximum production efficiency by 60.7%.

Specifically, the present disclosure has the following two inventive points: (1) a row-by-row mounting manner matching the component array is proposed and a placement point row-column grouping method matching the mounting manner is provided, such that without loss of the optimal solution, the search space is greatly narrowed: (2) a genetic algorithm coding and decoding method matching the row and column grouping method is provided such that specially-designed genetic operation is performed on each chromosome stage by stage, so as to quickly and stably obtain a global approximate optimal solution.

### BRIEF DESCRIPTIONS OF THE DRAWINGS

FIG. 1 is a flowchart illustrating a pick-mount process of a surface mount machine using a row-by-row mounting manner.

FIG. 2 is a schematic diagram of mounting an component array using a gantry type surface mount machine.

FIG. 3 is a flowchart illustrating a pick-mount process of a conventional surface mount machine.

FIG. 4 is a flowchart illustrating a placement path optimization method of a surface mount machine according to the present disclosure.

FIG. 5 is a schematic diagram illustrating a pick-placement path of an embodiment using the row-column grouping method of the present disclosure.

FIG. 6 is a schematic diagram illustrating a pick-placement path obtained without using the row-column grouping method in an embodiment.

FIG. 7 is a converging curve diagram of a placement path length according to an embodiment of the present disclosure.

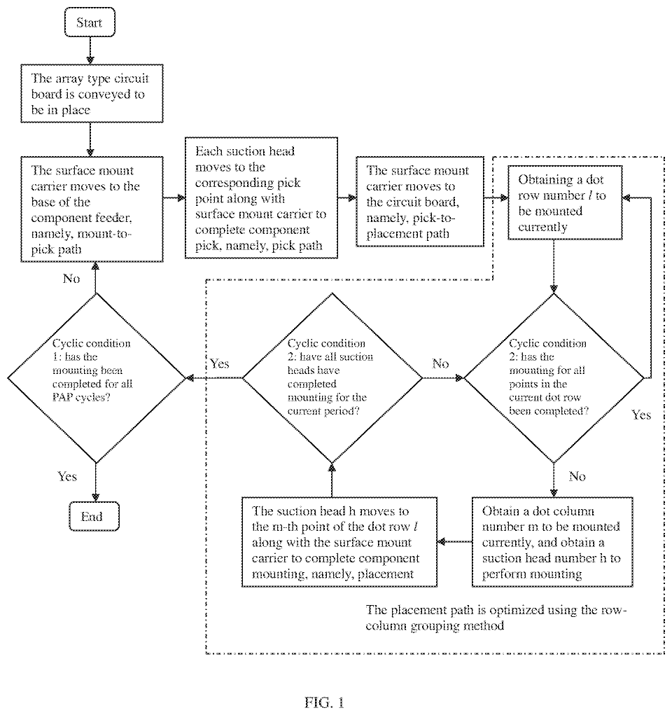

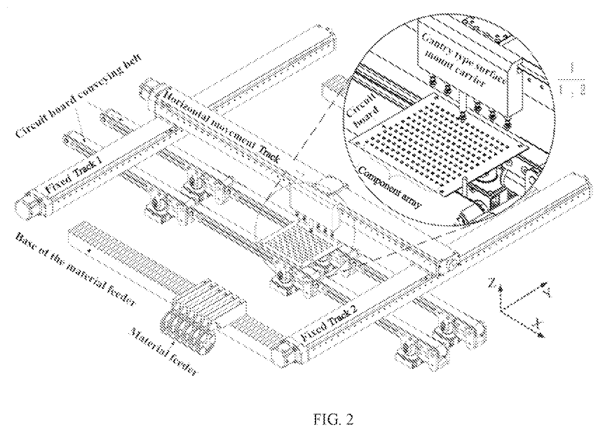

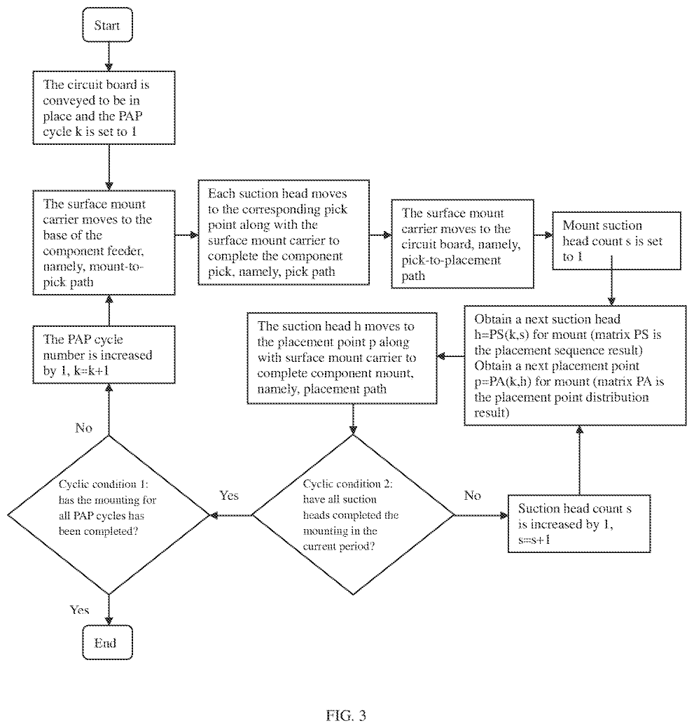

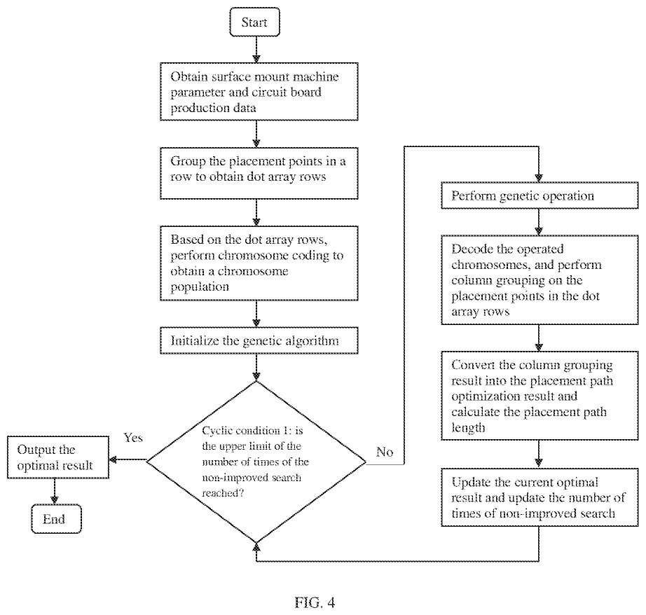

### DETAILED DESCRIPTIONS OF EMBODIMENTS

Embodiment 1: the present embodiment provides a placement path optimization method of a surface mount machine based on a row-column grouping genetic algorithm, which comprises the following steps:
at step 1, obtaining a surface mount machine parameter and a circuit board production data;
at step 2, grouping placement points in a row to obtain dot array rows;
at step 3, encoding the row grouping results of the placement points to generate a chromosome population;
at step 4, decoding the chromosomes to obtain column grouping results of the placement points within the dot array rows, converting the column grouping results into placement path optimization results, calculating the placement path lengths, and outputting them;
at step 5, setting parameters and loop conditions for the genetic algorithm;
at step 6, based on the crossover operator, operating each chromosome and updating the placement path optimization result by comparison and selection;
at step 7, based on the mutation operator, operating each chromosome and updating the placement path optimization result by comparison and selection;
at step 8, outputting the optimal placement path optimization result.

Embodiment 2: the difference between this embodiment and embodiment 1 is that the specific process of obtaining the surface mount machine parameter and the circuit board production data in step 1 comprises:
at step 11, the surface mount machine parameter is obtained: the surface mount machine parameter comprises a total number H of suction heads, and an index of the suction heads in a sequence of increasing along X axis is numbered as hϵ[1, . . . , H], and a spacing between the suction heads is DI;
at step 12, the circuit board production data is obtained: the circuit board production data comprises a total number P of placement points, a sequence number of each placement point is pϵ[1, . . . , P], an array xyn₀ with a row number 3 and a column number P is initialized, the first two rows of the array store the coordinate of each placement point, the third row stores placement point number, and the X coordinate and Y coordinate of the P-th placement point are xyn₀(1,p) and xyn₀(2,p), where its placement point number is xyn₀(3,p)=p;
at step 13, each placement point is sorted in an increasing sequence of Y coordinates: i₀=sort(xyn₀(2,:)), where sort performs sorting on components in the array in an increasing sequence and returns an index of the sorted components in the original array, xyn₀=xyn₀(:,i₀);
notes: “:” represents obtaining all values of this dimension in auto increment manner, and xyn₀(2,:) represents obtaining Y coordinates of all placement points, which are described below:
“1:1: P” represents an array increased with an increment of 1 from the start amount 1 to the end amount P, i.e. [1, . . . , P], “P:−1:1” represents an array increased with an increment of −1 from the start amount P to 1, i.e. [P,P−1, . . . , 1]; since the auto increment (increment 1) search is often used, 1:1:P is simplified as 1:P: when indexing is performed on the array if the start amount is 1 and the end amount is just the number of the components in the dimension, xyn₀(2,1:P) is further simplified as xyn₀(2,:);
xyn₀(:,i₀) represents obtaining each column in the xyn₀ in the sequence of the array i₀, xyn₀=xyn₀(:,i₀) refers to re-storing xyn₀(:,i₀) into xyn₀ so as to re-sort each column in xyn₀ based on the array i₀;
notes: the sort result is described; if the original array before sorting is o₁=[2 3 1], the results of the array sorted in increasing sequence are o₂=[1 2 3], and thus the sequence of each component of o₂ in o₁ is o₃=sort(o₁)=[3 1 2], namely, o₂=o₁(o₃) is always established;
at step 14, a total number of PAP cycles is K=┐P/H┘, where the symbol └ ┘ refers to performing up-rounding on the value therein, and a number of suction heads performing mounting in the last period is H₁=P−(K−1)*H;
wherein * represents the multiplication sign.

Other steps and parameters are the same as the specific embodiment 1.

Embodiment 3: the difference of this embodiment from embodiment 1 or 2 is that: the specific process of grouping placement points in a row to obtain the dot array rows in step 2 comprises:
at step 21, xyn₁=xyn₀ is assigned: the boundary layer thickness ab=2 of the placement points identified as the same dot array row is initialized: the count variable of the dot array rows is initialized l=0, the count variable of the dot array row type N=0, and the length array of the dot array row is M₁=[ ] (M₁ is initialized and assigned as an empty array);
at step 22, it is determined whether xyn₁ is an empty array: if yes, it indicates all placement points have been grouped, and the total number of dot array rows L=l, step 3 is performed and otherwise, step 23 is performed.
at step 23, in the current ungrouped placement points, a placement point number forming the dot array rows with the placement point with the minimum Y coordinate is obtained as i₁=find(xyn₁(2,:)<ab+xyn₁(2,1)), and step 24 is performed;
wherein find represents a sequence number of the components satisfying the condition in the parentheses in the array in the parentheses after find: xyn₁(2,:) represents the Y coordinates of all placement points: xyn₁(2,1) represents the Y coordinate of the first placement point;
at step 24, the count variable l=l+1 is updated: the meta array AE{l}=xyn₁(:,i₁) is initialized and assigned; each placement point is sorted in an increasing sequence of X coordinates, namely, i₀=sort(AE{l}(1,:)) and AE{l}=AE{l}(:,i₀); information xyn₁(:,i₁)=[ ] of the placement points grouped is cleared; step 25 is performed;
Notes: due to the complexity of the problem, the dimension of storing data is high such that the arrays with unfixed storage lengths are required in the arrays; at this time, the array with the braces { } as index mark is referred to as meta array;
wherein xyn₁(:,i₁) represents obtaining each column in xyn₁ in a sequence of the array i₁, AE{l}=xyn₁(:,i₁) stores information of each placement point in the l-th dot array row; AE{7} (1,:) represents the information of the X coordinate of each placement point in the l-th dot array row; AE{l}(:,i₀) represents obtaining each column in AE{l} in a sequence of the array i₀, and AE{l}=AE{l}(:,i₀) refers to re-storing AE{l}(:,i₀) into AE{l}, so as to re-sort each column in AE{l} based on the array i₀;
at step 25, it is determined whether N=0 is present, if yes, step 26 is performed and if not, step 27 is performed;
at step 26, the count variable N=1 is updated to obtain the current dot array row length as M₀=col(AE{l}), wherein col represents obtaining a number of columns in the array in the parentheses after col and the dot array row length array M₁=[M₁ M₀] is updated; a distance AX{N}=AE{l}(1,:)−AE{l}(1,1) between each point and the first point in the current dot array row is calculated: the meta array AL{N}=l is initialized and assigned to store a dot array row index contained in each dot array row type: step 22 is repeated;
notes: AE{l}(1,1) represents the X coordinate of the first placement point in the l-th dot array row; M₁=[M₁ M₀] represents adding a new component M₀ to the end of the current M₁ array;
at step 27, a dot array row type to which the current dot array row belongs is divided;
at step 271, the count variable n=1 of the dot array row type is initialized;
at step 272, if n>N, it indicates that one traversal has been completed for the divided dot array row type, and step 22 is repeated and otherwise, step 273 is performed;
at step 273, the current dot array row length M₀=col(AE{l}) is obtained: it is determined whether M₁(n)=M₀ is present: if yes, the distance ax=AE{l}(1,:)−AE{l}(1,1) between each point and the first point in the current dot array row is calculated, and step 274 is performed and otherwise, step 275 is performed;
wherein M₁(n) represents the dot array row length in the n-th dot array row type;
at step 274, ba=sum(|AX{n}−ax|)/M₀ is assigned, wherein the symbol ∥ represents an absolute value of each value therein, and sum represents performing summing for the array in the parentheses after sum: it is determined whether ab>ba is present, and if yes, it indicates that the current dot array row belongs to the n-th type of dot array rows, the meta array AL{n}=[AL{n}l] is updated, n=N+1 is assigned, and step 272 is repeated and otherwise, step 275 is performed;
wherein AL{n} represents each dot array row index in the n-th dot array row type; AL{n}=[AL{n}l] represents adding a new component l to the end of AL{n}, namely, adding the l-th dot array row in the n-th dot array type;
at step 275, it is determined whether n=N is present: if yes, it indicates that the current dot array row does not belong to any divided dot array row type, and step 276 is performed, and otherwise, the count variable n=n+1 is updated and step 272 is repeated;
at step 276, the count variable N=N+1 is updated, the dot array row length array M₁=[M₁ M₀] is updated, the arrays AX{N}=ax and AL{N}=l are initialized and assigned: n=N+1 is assigned and step 272 is repeated.

Other steps and parameters are the same as embodiment 1 or 2.

Embodiment 4: the difference of this embodiment from embodiments 1 to 3 is that: the specific process of performing chromosome coding on the row grouping result of the placement points to obtain the chromosome population in step 3 comprises:
at step 31, the number of the chromosome populations is initialized to W=40; with w as chromosome index, the chromosome population U{w}ϵ[U{1} . . . , U{W} ] is initialized to empty array: the array D with a row number 1 and a column number W with all components being zero is initialized to store a placement path length corresponding to each chromosome: the maximum variable inf=100000 is initialized: the optimal placement path length DTb=inf is initialized: the number of daughter chromosomes is initialized to V=3; with v as daughter chromosome index, each daughter chromosome u{v}ϵ=[u{1}, . . . , u{V} ] is initialized to empty array: the count w=1 of the number of the chromosome populations is initialized;
at step 32, the number of placement points to be mounted across the dot array row is obtained, which comprises the following specific operations;
at step 321, the dot array row type count n=1 is initialized: the array AC with a row number 1 and a column number N with all components being zero is initialized to store the number of the dot array rows contained in each dot array row type: the array K₁ with a row number 1 and a column number N with all components being zero is initialized to store the number of the PAP cycles for filling the placement points in each type of dot array rows: NG=0 is initialized and assigned to store gene loca in the chromosome; the array aj with a row number 1 and a column number L with all components being zero is initialized to store the number of placement points mounted across row in each dot array row: NJ=0 is initialized and assigned to store a total number of placement points to be mounted across row;
at step 322, if n>N, NG=NG+NJ+H is updated and step 33 is performed, and otherwise, step 323 is performed;
at step 323, K₁(n)=└M₁(n)/H┘ is calculated wherein the symbol └ ┘ represents performing down-rounding for the value therein;
wherein K₁(n) represents a number of PAP cycles required to complete mounting for one n-th type of dot array rows;
at step 324, the number of placement points to be mounted across rows in the current type of dot array rows is nj=M₁(n)−H*K₁(n): AC(n)=col(AL{n}), NJ=NJ+AC(n)*nj, NG=NG+M₁(n) are updated; the count variable l₁=1 is initialized;
wherein AC(n) represents the number of dot array rows contained in the n-th type of dot array rows;
at step 325, it is determined whether l₁>AC(n) is present: if yes, the count variable n=n+1 is updated and step 322 is repeated, and otherwise, step 326 is performed;
at step 326, a dot array row sequence number l=AL{N} (l₁) is obtained and aj(l)=nj is assigned; the count variable l₁=l₁+1 is updated, and step 325 is repeated;
notes: l=AL{N}(l₁) represents an index of the l₁-th dot array row in the N-type of dot array rows; aj(l) represents the number of placement points to be mounted across row in the dot array row with the index l;
at step 33, the daughter chromosomes u{1} of the placement point distribution sequence of various types of dot array rows are obtained, which includes the following specific operations:
at step 331, corresponding to each dot array row type nϵ[1, . . . , N], the meta array pa{n}ϵ[pa{1}, . . . , pa{N}] with a row number M₁(n) and a column number 1 with all components being zero is initialized to store the placement point distribution sequence of each type of dot array rows, wherein pa{n} is referred to as the distribution sequence chromosomes of the n-type of dot array rows: the dot array row type count n=1 is initialized;
at step 332, if n>N, step 34 is performed and otherwise, step 333 is performed;
at step 333, pa{n}=randperm([1, . . . , M₁(n)]), wherein randperm represents generating a random permutation of the array in the parentheses after randperm: {1}{n}=pa{n} is assigned: the count variable n=n+1 is updated and step 332 is repeated;
notes: u is a two-dimensional meta array, wherein u{1} is the first meta array in u, u{1}{n} is the n-th array in u{1}, namely, the distribution sequence chromosomes of the n-th type of dot array rows;
at step 34, the placement sequence daughter chromosomes u{2}=randperm([1, . . . , NJ]) across dot array row are obtained: step 35 is performed;
at step 35, the daughter chromosomes u{3}=randperm([1, . . . , H]) selected by the suction heads in the last period are obtained: step 36 is performed;
at step 36, U{w}=u is assigned: with u as input, step 4 is performed to obtain an output containing the corresponding placement path optimization result and placement path length DT, D(w)=DT: step 37 is performed:

wherein u represents one chromosome, i.e. one set of daughter chromosomes, U{w}=u represents that u is stored as the w-th chromosome in the chromosome population; DT represents the placement path length corresponding to the chromosome u, D(w)=DT represents the placement path length DT corresponding to the w-th chromosome in the chromosome population:
at step 37, it is determined whether DTb>D(w): if yes, the optimal placement path length DTb=D(w) is updated, and the optimal solution index wb=w is updated, and otherwise, no processing is performed: step 38 is performed;
at step 38, the count variable w=w+1 is updated, and if w>W, step 5 is performed and otherwise, step 33 is performed.

Other steps and parameters are the same as embodiments 1 to 3.

Embodiment 5: the difference of this embodiment from embodiments 1 to 4 is that: the specific process of performing chromosome decoding to obtain a column grouping result of the placement points in the dot array rows and converting the column grouping result into a placement path optimization result, and calculating and outputting a placement path length in step 4 comprises:
at step 41, initialization is performed, which comprises the following specific operations:
at step 411, the placement path length DT=0, the PAP cycle count k=0 and the sucking-rod traversed array ah=[1, . . . , H] are initialized and assigned;
at step 412, the two-dimensional array PA with a row number K and a column number H with all components being zero is initialized to store a placement point distribution result, wherein the component PA(k,h) is used to store a placement point number mounted by the h-th suction head in the k-th PAP cycle: the two-dimensional array PS with a row number K and a column number H with all components being zero is initialized to store the placement sequence result, wherein the component PS(k,s) is used to store the s-th suction head number performing mounting in the k-th PAP cycle: the two-dimensional array PL with a row number K and a column number H with all components being 1 is initialized, wherein the component PL(k,h) is used to store the dot array row sequence number mounted by the h-th suction head in the k-th PAP cycle: the two-dimensional array PM with a row number K and a column number H with all components being 1 is initialized, wherein the component PM(k,h) is used to store a sequence number, in the dot array rows, of the placement point mounted by the h-th suction head in the k-th PAP cycle: the two-dimensional array PX with a row number K and a column number H with all components being inf is initialized, wherein the component PX(k,h) is used to store the X coordinate of the surface mount carrier used by the h-th suction head for mounting in the k-th PAP cycle: the two-dimensional array PY with a row number K and a column number H with all components being inf is initialized, wherein the component PY(k,h) is used to store the Y coordinate of the surface mount carrier used by the h-th suction head for mounting in the k-th PAP cycle: the two-dimensional array TJ with a row number L and a column number H with all components being zero is initialized, wherein the component TJ(l,h) is used to store the sequence number, in the I-th dot array row, of the h-th placement point to be mounted across row in the l-th dot array row;
at step 413, L₁=L+1 is assigned: the two-dimensional array AJ with a row number L₁ and a column number 1 with all components being zero is initialized to accumulate the number of the placement points to be mounted across row: AJ(L₁)=NJ+1 is assigned: the dot array row count variable l=2 is initialized;
wherein AJ(L₁) represents an upper limit of the number of the cross-row placement points;
at step 414, if l>L, the dot array row type count n=1 is initialized, and step 42 is performed and otherwise, step 415 is performed;
at step 415, AJ(l)=AJ(l−1)+aj(l−1): the count variable l=l+1 is updated, and step 414 is repeated;
wherein AJ(l) represents the number of cross-row placement points distributed when row-by-row distribution is performed to the I-th dot array row;
at step 42, column grouping is performed on the placement points in the dot array row filling up the full period, which comprises the following specific operations:
at step 421, if n>N, step 43 is performed and otherwise, step 422 is performed;
at step 422, the temporary chromosome q₀=u{1}{n} is assigned; and the count variable k₁=1 is initialized;
at step 423, it is determined whether k₁>K₁(n) is present: if yes, the count variable l₂=1 is initialized, and step 427 is performed and if not, step 424 is performed;
at step 424, ap=q₀(ah) is assigned, and q₀(ah)=[ ] is updated: the count variable l₁=1 is initialized;
wherein q₀=u{1}{n} represents that q₀ stores the distribution sequence chromosomes of the n-th type of dot array rows, q₀(ah) represents an array formed by the first to H-th components in the distribution sequence chromosomes of the n-th type of dot array rows;
at step 425, it is determined whether l₁>AC(n) is present: if yes, the count variable k₁=k₁+1 is updated, and step 423 is repeated: if not, step 426 is repeated;
at step 426, the PAP cycle count k=k+1 is updated: the dot array row sequence number l=AL{N}(l₁) is obtained; PL(k,:)=PL(k,:)*l, PM(k,:)=ap, PX(k,:)=AE{l}(1,ap)−(ah−1)*DI, PY(k,:)=AE{l}(2,ap), and PA(k,:)=AE{l}(3,ap) are assigned: the count variable l₁=l₁+1 is updated, and step 425 is repeated;
wherein PL(k,:) represents a dot array row sequence number mounted by each suction head in the k-th PAP cycle: PM(k,:) represents a sequence number, in the dot array row, of the placement point mounted by each suction head in the k-th PAP cycle: PX(k,:) represents the X coordinate of the surface mount carrier when each suction head performs mounting in the k-th PAP cycle: PY(k,:) represents the Y coordinate of the surface mount carrier when each suction head performs mounting in the k-th PAP cycle: PA(k,:) represents the placement point number mounted by each suction head in the k-th PAP cycle: AE{l}(1,ap) represents the X coordinate of the placement point obtained in the I-th dot array row in the sequence of the array ap; AE{l}(2,ap) represents the Y coordinate of the placement point obtained in the l-th dot array row in the sequence of the array ap; AE{l}(3,ap) represents the placement point number obtained in the l-th dot array row in the sequence of the array ap;
at step 427, it is determined whether 12>AC(n) is present: if yes, the count variable n=n+1 is updated, and step 421 is repeated, and if not, step 428 is performed;
at step 428, the dot array row sequence number l=AL{N}(l₂) is obtained; TJ(l,1:aj(1))=q₀ is assigned: the count variable l₂=l₂+1 is updated, and step 427 is repeated;
wherein AL{N} (12) represents an index of the l₂-th dot array row in the N-th type of dot array rows; TJ(l,1:aj(l)) represents the sequence number, in the l-th dot array row, of the first to aj(l)-th placement points to be mounted across row in the l-th dot array row;
at step 43, column grouping is performed on the placement points to be mounted across rows, which comprises the following specific operations:
at step 431, the temporary chromosome q₁=u{2} is assigned: the count variable l₀=1 of the first dot array row being distributed is initialized: the number of the undistributed placement points in the dot array row being distributed is g₀=aj(1): a total number of PAP cycles for cross-row mounting is K₂=[NJ/H]; the PAP cycle count k₂=1 for cross-row mounting is initialized;
wherein aj(1) represents the number of placement points to be mounted across row in the first dot array row;
at step 432, it is determined whether k₂>K₂ is present: if yes, step 44 is performed and if not, the placement point accumulated variable g₁=g₀ is assigned, and the search count variable l₁=l₀+1 of to-be-distributed dot array row is initialized, and step 433 is performed;
at step 433, it is determined whether l₁>L is present: if yes, step 435 is performed and if not, step 434 is performed;
at step 434, g₁=g₁+aj(l₁) is updated: it is determined whether g₁>H: if yes, it indicates that the currently-accumulated placement points are sufficient to fill up one PAP cycle, l₀=l₁ and l₁=L+1 are updated, and step 433 is repeated, and otherwise, l₁=l₁+1 is updated, and step 433 is repeated;
wherein aj(l₁) represents the number of placement points to be mounted across row in the l₁-th dot array row;
at step 435, decoding is performed based on q₁ to only retain H placement points satisfying conditions so as to fill up one PAP cycle: i₂=find(q₁<AJ(l₀+1)), i₃=find(q₁(i₂)>AJ(l₀)) and the number of the remaining placement points g₀=g₁−H, g₂=aj(l₀)−g₀+1 is assigned, i₄=i₃(g₂:aj(l₀)) is assigned, i₂(i₄)=[ ] is updated, the chromosome segments to be distributed in the current period are pq=q₁(i₂), q₁(i₂)=[ ] is updated: the PAP cycle count k=k+1 is updated: the suction head count variable h=1 is assigned:

wherein AJ(l₀+1) represents the number of the cross-row placement points distributed when row-by-row distribution is performed to the (l₀+1)-th dot array row: AJ(l₀) represents the number of the cross-row placement points distributed when row-by-row distribution is performed to the l₀-th dot array row: q₁(i₂) represents components obtained from the temporary chromosomes q₁ in the sequence of the array i₂; aj(l₀) represents the number of placement points to be mounted across row in the dot array row with the index of i₀: i₂ is a temporary variable representing an component sequence less than AJ(l₀+1) in q₁:i₃ is a temporary variable representing an component sequence greater than AJ(l₀) in q₁(i₂): 14=i₃(g₂:aj(l₀)) represents the g₂-th to aj(l₀)-th component in i₃; and i₂(i₄) represents the components obtained from i₂ in the sequence of the array i₄;
at step 436, it is determined whether h>H is present; if yes, the count variable k₂=k₂+1 is updated, and step 432 is repeated, and if not, step 437 is performed;
at step 437, i₅=find(AJ≥pq(h)) is assigned, the dot array row number where the current placement point is located is l=i₅(1)−1, the sequence number of the placement point in the dot array row is ap=TJ(l,pq(h)−AJ(l)): PL(k,h)=l, PM(k,h)=ap, PX(k,h)=AE{l}(1,ap)−(h−1)*DI, PY(k,h)=AE{l}(2,ap), and PA(k,h)=AE{l}(3,ap) are assigned: the count variable h=h+1 is updated and step 436 is repeated;
wherein is represents the component sequence number no less than pq(h) in AJ; pq(h) represents the h-th component in the chromosome segment pq;
at step 44, column grouping is performed on the placement points in the last period, which comprises the following specific operations;
at step 441, if H:>0, it indicates that there is an idle suction head in the last period, and step 442 is performed, and otherwise, step 45 is performed;
at step 442, the temporary chromosome q₂=u{3}(1:H₁) is assigned: sorting is performed on the components in q₂ in an increasing sequence, namely, i₀=sort(q₂) and q₂=q₂(i₀); PL(K,:)=PL(K,:)*L₁ is assigned; the suction head count variable s=1 is assigned;
wherein u{3}(1:H₁) represents the suction heads select the first to H₁-th component in the daughter chromosomes in the last period;
at step 443, it is determined whether s>H₁; if yes, step 45 is performed and if not, step 444 is performed;
at step 444, i₆=find(AJ≥q₁(s)) is assigned: the dot array row number where the current placement point is located is l=i₆(1)−1, and the sequence number of the placement point in the dot array row is ap=TJ(l,q₁(s)−AJ(l));
wherein i₆ represents an component sequence number no less than q₁(s) in AJ: q₁(s) represents the s-th component in the temporary chromosome q₁; i₆(1) represents the first component sequence number no less than q₁(s) in AJ;
at step 445, the suction head number h=q₂(s) is obtained: PL(K,h)=l, PM(K,h)=ap, PX(K,h)=AE{l}(1,ap)−(h−1)*DI, PY(K,h)=AE{l}(2,ap), and PA(K,h)=AE{l}(3,ap) are assigned: the count variable s=s+1 is updated and step 443 is performed;
wherein q₂(s) represents the s-th component in the temporary chromosome q₂: PL(K,h) is used to store a dot array row sequence number mounted by the h-th suction head in the K-th PAP cycle: PM(K,h) is used to store the sequence number, in the dot array row, of the placement point mounted by the h-th suction head in the K-th PAP cycle: PX(K,h) is used to store the X coordinate of the surface mount carrier when the h-th suck rod performs mounting in the K-th PAP cycle: PY(K,h) is used to store the Y coordinate of the surface mount carrier when the h-th suck rod performs mounting in the K-th PAP cycle: PA(K,h) is used to store the placement point number mounted by the h-th suction head in the K-th PAP cycle;
at step 45, based on the column grouping result of the placement points, the placement path optimization result is obtained and the placement path length is calculated, which comprises the following specific operations;
at step 451, the PAP cycle count is k=1;
at step 452, if k>K, DT, PA, and PS are outputted to call the original steps (those calling the step 4 are: step 36, step 661, step 662, step 761) of the step 4 and otherwise, step 453 is performed;
at step 453, firstly, based on an increasing sequence of X coordinates, the placement points of the current PAP cycle are sorted: i₇=sort(PX(k,:)), PX(k,:)=PX(k,i₇), PY(k,:)=PY(k,i₇), PL(k,:)=PL(k,i₇);
next, based on an increasing sequence of dot array row sequence numbers, each placement point is sorted again: i₈=sort(PL(k,:)), PX(k,:)=PX(k,i₈), PY(k,:)=PY(k,i₈), PL(k,:)=PL(k,i₈): the placement sequence result in the current PAP cycle is PS(k,:)=i₇(i₈);
wherein i₇ represents an index of each component in the original array after sorting is performed on the components in array PX(k,:) in an increasing sequence: PX(k,i₇) represents obtaining the X coordinate of the surface mount carrier in the K-th PAP cycle with i₇ as the suction head index: PY(k,i₇) represents obtaining the Y coordinate of the surface mount carrier in the K-th PAP cycle with i₇ as the suction head index: PL(k,i₇) represents obtaining the dot array row sequence number in the K-th PAP cycle with i₇ as the suction head index: is represents an index of each component in the original array after sorting is performed on the components in the array PL(k,:) in an increasing sequence: PX(k,i₈) represents the X coordinate of the surface mount carrier in the K-th PAP cycle with is as suction head index: PY(k,i₈) represents the Y coordinate of the surface mount carrier in the K-th PAP cycle with is as suction head index: PL(k,i₈) represents obtaining the dot array row sequence number in the K-th PAP cycle with is as the suction head index;
at step 454, the suction head count variable s=2 is assigned: if k=K, H₂=H₁; otherwise, H₂=H; step 455 is performed;
at step 455, if s>H₂, the count variable k=k+1 is updated, and step 452 is repeated and otherwise, step 456 is performed;
at step 456, a Chebyshev distance between the current mount coordinate and a previous mount coordinate is dt=max(|PX(k,s)−PX(k,s−1)|,|PY(k,s)−PY(k,s−1)|): the placement path length DT=DT+dt is updated: the count variable s=s+1 is updated, and step 455 is repeated;
wherein PX(k,s) is used to store the X coordinate of the surface mount carrier when the s-th suction head performs mounting in the k-th PAP cycle: PY(k,s) is used to store the Y coordinate of the surface mount carrier when the s-th suction head performs mounting in the k-th PAP cycle.

Other steps and parameters are the same as the embodiments 1 to 4.

Embodiment 6: the difference of this embodiment from embodiments 1 to 5 is that: the specific process of setting the parameter and the cyclic condition of the genetic algorithm in step 5 comprises the following steps:
at step 51, the crossover probability RC=0.6 and the mutation probability RM=0.02 of the genetic algorithm are initialized: the upper limit IC=RC*W of the number of times of the crossover operation is calculated, the upper limitIM=RM*W*NG of the number of times of the mutation operation is calculated, the upper limit IT=2*[(NG)^{0.5}] of the number of times of the non-improved search is calculated: wherein the symbol [ ] refers to performing up-rounding for the value therein: the non-improved search count variable it=0 is initialized;
at step 52, if it>IT, it indicates that the upper limit of the number of times of the non-improved search is reached, and step 8 is performed; otherwise, the crossover operation count ic=1 is initialized, and step 53 is performed;
at step 53, if ic>IC, it indicates that the upper limit of number of times of the crossover operation is reached, the mutation operation count im=1 is initialized, and step 54 is performed, and otherwise, step 6 is performed;
at step 54, if im>IM, it indicates that the upper limit of the number of times the mutation operation is reached, step 55 is performed and otherwise, step 7 is performed;
at step 55, [db,wo]=min(D) is obtained, wherein min represents the minimum value of the array in the parentheses after min, db is the minimum placement path length obtained at present, wo is a chromosome index for achieving the optimal placement path: it is determined whether DTb>db is present; if yes, the optimal placement path length DTb=db is updated, and the optimal solution index wb=wo is updated, and the count variable it-0 is updated: if not, the count variable it=it+1 is updated and step 52 is repeated.

Other steps and parameters are the same as the embodiments 1 to 5.

Embodiment 7: the difference of this embodiment from embodiments 1 to 6 is that: the specific process of, based on the crossover operator, operating each chromosome and updating the placement path optimization result by comparison and selection in step 6 comprises the following steps:
at step 61, based on roulette wheel selection, two chromosomes subjected to crossover operation are selected, which comprises the following steps;
at step 611, the arrays E and SR with a row number 1 and a column number W with all components being zero are initialized: each chromosome wϵ[1, . . . , W} is traversed: E(w)=1/D(w) is assigned, the selection probability SR(w)=E(w)/sum(E) of each chromosome is assigned: the chromosome serial numbers w₀=0 and w₁=0 selected are initialized;
wherein E(w) is the reciprocal of D(w);
at step 612, it is determined whether w₀=w₁ is present: if yes, step 613 is performed and otherwise, the temporary chromosome population U₁{w₃}ϵ[U₁]{1}, . . . , U₁{4}], U₁{1}=U{w₀}, U₁{2}=U{w₁}, U₁{3}=U{w₀}, U₁{4}=U{w₁} are initialized: the array D₁ with one row and four columns is initialized and D₁=[D(w₀) D(w₁) D(w₀) D(w₁)] is assigned and step 62 is performed;
wherein U₁{1} represents the first chromosome in the temporary chromosome population: U₁{2} represents the second chromosome in the temporary chromosome population: U₁{3} represents the third chromosome in the temporary chromosome population; U₁{4} represents the fourth chromosome in the temporary chromosome population: U{w₀} represents the w₀-th chromosome in the chromosome population: U{w₁} represents the w₁-th chromosome in the chromosome population; D(w₀) represents the placement path length corresponding to the w₀-th chromosome in the chromosome population; D(w₁) represents the placement path length corresponding to the w₁-th chromosome in the chromosome population;
at step 613, the selection probabilities sr₀=rand(1) and sr₁=rand(1) are generated, wherein rand(1) refers to generating a random number between 0 and 1: the chromosome count variable w₂=1 is initialized and the probability accumulated variable sr=0 is initialized; wherein rand(1) refers to generating a random number between 0 and 1;
at step 614, if w₂>W, the chromosome count variable w₂=1 is reset, and the probability accumulated variable sr=0 is cleared to zero, and step 616 is performed and otherwise, step 615 is performed;
at step 615, sr=sr+SR(w₂) is updated: it is determined whether sr<sr₀ is present: if yes, w₂=w₂+1 is updated and if not, w₀=w₂ is stored, and w₂=w+1 is assigned: step 614 is repeated;
wherein SR(w₂) represents the selection probability of the w₂-th chromosome;
at step 616, if w₂>W, step 612 is repeated and otherwise, step 617 is performed;
at step 617, sr=sr+SR(w₂) is updated: it is determined whether sr<sr₁ is present: if yes, w₂=w₂+1 is updated, and if not, w₁=w₂ is stored and w₂=W+1 is assigned: step 616 is repeated;
at step 62, if it≤[IT/4], step 63 is performed, and otherwise, step 64 is performed;
at step 63, in the two selected chromosomes, a crossover operation is performed on the placement point distribution sequence daughter chromosomes of each type of dot array rows, which comprises the following specific operations;
at step 631, the count variable n=1 of the dot array row type is initialized: at step 632, if n>N, step 64 is performed and otherwise, step 633 is performed;
at step 633, two chromosome segments pu₀={3}{1}{n} and pu₁=U₁{4}{1}{n} to be operated are selected, and the chromosome segment length is npu=M₁(n);
wherein U₁ is a three-dimensional array, wherein U₁{3} represents the third chromosome in the temporary chromosome population, U₁{3}{1} represents obtaining the first daughter chromosome in U₁{3}, namely, the placement point distribution sequence daughter chromosome of each type of dot array rows, U₁{3}{1}{n} represents obtaining the placement point distribution sequence of the n-th type of dot array rows in the daughter chromosome U₁{3}{1}: U₁{4} represents the fourth chromosome in the temporary chromosome population, U₁{4}{1} represents obtaining the first daughter chromosome in U₁{4}, namely, the placement point distribution sequence daughter chromosome of each type of dot array rows, U₁{4}{1}{n} represents the placement point distribution sequence of the n-th type of dot array rows in the daughter chromosome U₁{4}{1};
at step 634, with pu₀, pu₁, and npu as input, step 65 is performed and pu₂ and pu₃ subjected to crossover operation are obtained from the output, and U₁{3}{1}{n}=pu₂ and U₁{4}{1}{n}=pu₃ are assigned: the count variable n=n+1 is updated, and step 632 is repeated;
at step 64, a crossover operation is performed on the cross-dot-array-row placement sequence daughter chromosome in the two selected chromosomes and the daughter chromosome selected by the suction head in the last period, which comprises the following specific operations;
at step 641, two chromosome segments pu₀=U₁{3}{2} and pu₁=U₁{4}{2} to be operated are obtained, the chromosome segment length is npu=NJ; with pu₀, pu₁, npu as input, step 65 is performed and pu₂ and pu₃ subjected to crossover operation are obtained from the output, and U₁{3}{2}=pu₂ and U₁{4}{2}=pu₃ are assigned: step 642 is performed;
wherein U₁{3} represents the third chromosome in the temporary chromosome population, U₁{3}{2} represents obtaining the second daughter chromosome in U₁{3}, namely, the cross-dot-array-row placement sequence daughter chromosome: U₁{4} represents the fourth daughter chromosome in the temporary chromosome population, U₁{4}{2} obtaining the second daughter chromosome in U₁{4}, namely, the cross-dot-array-row placement sequence daughter chromosome;
at step 642, two chromosome segments pu₀=U₁{3}{3} and pu₁=U₁{4}{3} to be operated are obtained, the chromosome segment length is npu=H: with pu₀, pu₁, npu as input, step 65 is performed and pu₂ and pu₃ subjected to crossover operation are obtained from the output, and U₁{3}{3}=pu₂ and U₁{4}{3}=pu₃ are assigned: step 643 is performed;
wherein U₁{3} represents the third chromosome in the temporary chromosome population, U₁{3}{3} represents obtaining the third daughter chromosome in U₁{3}, namely, the daughter chromosome selected by the suction head in the last period: U₁{4} represents the fourth chromosome in the temporary chromosome population, U₁ {4}{3} represents obtaining the third daughter chromosome in U₁{4}, namely, the daughter chromosome selected by the suction head in the last period;
at step 643, step 66 is performed;
at step 65, a crossover operation is performed on the input two chromosome segments, which comprises the following specific operations;
at step 651, the number of the components crossed is nc₀=3: the start component number crossed is nc₁=└rand(1)*npu┘; it is determined whether nc₀−1+nc₁>npu is present: if yes, the end component number crossed is nc₂=nc₁−nc₀+1: the component array to be operated is NC₀=nc₂:nc₁; if not, nc₂=nc₁+nc₀−1 and NC₀=nc₁:nc₂; and NC₁=NC₀, NC₂=NC₀, pu₂=pu₀, pu₃=pu₁: the component count variable cc₀=1 in the operation region is initialized, and the number of the components in the operation region is CC=nc₀;
at step 652, if cc₀>CC, step 654 is performed and otherwise, step 653 is performed;
at step 653, it is determined whether an component is equal to pu₂(NC₀(cc₀)) in the array pu₃(NC₁): if yes, the index of the component is in cc₁, and NC₀(cc₀)=[ ], NC₁(cc₁)=[ ], CC=CC−1 are updated: if not, cc₀=cc₀+1 is updated: step 652 is repeated;
at step 654, CC=numel(NC₁), wherein numel represents the number of components in the array in the parentheses after numel: it is determined whether CC=0 is present: if yes, step 657 is performed, and if not, the count variable cc₀=1 is initialized and step 655 is performed;
at step 655, if cc₀>CC, step 657 is performed, and otherwise, step 656 is performed;
at step 656, cc₁=find(pu₀=pu₃(NC₁(cc₀))), pu₂(cc₁)=pu₀(NC₀(cc₀)) is updated; cc₁=find(pu₁=pu₂(NC₀(cc₀))), pu₃(cc₁)=pu₁(NC₁(cc₀)) is updated; cc₀=cc₀+1 is updated: step 655 is repeated;
at step 657, pu₂(NC₂)=pu₁(NC₂) and pu₃(NC₂)=pu₀(NC₂); pu₂ and pu₃ are outputted to call the original steps of step 65;
at step 66, two chromosomes obtained by crossover operation are decoded, and the corresponding placement path length is calculated: if it is superior to the result prior to the crossover operation, it is substituted into the chromosome population, which comprises the following specific operations;
at step 661, with u=U₁{3} as input, step 4 is performed to generate an output containing the corresponding placement path optimization result and the placement path length DT, and D₁(3)=DT is assigned;
at step 662, with u=U₁{4} as input, step 4 is performed to generate an output containing the corresponding placement path optimization result and the placement path length DT, and D₁(4)=DT is assigned;
at step 663, i₀=sort(D₁), wherein the indexes of two minimum components in D₁ are w₄=i₀(1) and w₅=i₀(2);
at step 664, the chromosome populations U{w₀}=U₁{w₄} and U{w₁}=U₁{w₅} are updated, D(w₀)=D₁(w₄) and D(w₁)=D₁(w₅) are updated: ic=ic+1 is updated, and step 53 is repeated:

Other steps and parameters are the same as the embodiments 1 to 6.

Embodiment 8: the difference of this embodiment from embodiments 1 to 7 is that: the specific process of, based on the mutation operator, operating each chromosome and updating the placement path optimization result by comparison and selection in step 7 comprises:
at step 71, based on roulette wheel selection, a chromosome subjected to mutation operation is selected, which comprises the following specific operations;
at step 711, each wϵ[1, . . . , W} is traversed, E(w)=1/D(w) is assigned, the selection probability of each chromosome SR(w)=E(w)/sum(E) is assigned: the chromosome serial number selected is initialized to w₀=0;
at step 712, the selection probability sr₀=rand(1) is generated: the chromosome count variable w₂=1 is initialized, and the probability accumulated variable sr=0 is initialized;
at step 713, if w₂>W, step 715 is performed and otherwise, step 714 is performed;
at step 714, sr=sr+SR(w₂) is updated: it is determined whether sr<sr₀ is present: if yes, w₂=w₂+1 is updated, and if not, w₀=w₂ is stored, and w₂=W+1 is assigned: step 713 is repeated;
at step 715, the temporary chromosome u₀=U{w₀} is initialized; D₂=D(w₀) is initialized and assigned: step 72 is performed;
at step 72, if it≤[IT/4], step 73 is performed and otherwise, step 74 is performed;
at step 73, in the selected chromosomes, mutation operation is performed on the placement point distribution sequence daughter chromosomes of each type of dot array rows, which comprises the following specific operations;
at step 731, the count variable n=1 of the dot array row type is initialized;
at step 732, if n>N, step 74 is performed and otherwise, step 733 is performed;
at step 733, the chromosome segment pu₀=u₀{1}{n} to be operated is obtained, and the chromosome segment length is npu=M₁(n);
at step 734, with pu₀ and npu as input, step 75 is performed and pu₁ subjected to mutation operation is obtained from the output, and u₀{1}{n}=pu₁ is assigned: the count variable n=n+1 is updated and step 732 is repeated;
at step 74, mutation operation is performed on the cross-dot-array-row placement sequence daughter chromosome in the two selected chromosomes and the daughter chromosome selected by the suction head in the last period, which comprises the following specific operations;
at step 741, the chromosome segment pu₀=u₀{2} to be operated is obtained, and the chromosome segment length is npu=NJ; with pu₀ and npu as input, step 75 is performed, and pu₁ subjected to mutation operation is obtained from the output, and u₀{2}=pu₁ is assigned;
at step 742, the chromosome segment pu₀=u₀{3} to be operated is obtained, and the chromosome segment length is npu=H: with pu₀ and npu as input, step 75 is performed, and pu₁ subjected to mutation operation is obtained from the output, and u₀{4}=pu₁ is assigned: at step 743, step 76 is performed;
at step 75, mutation operation is performed on the input chromosome segment, which comprises the following specific operations;
at step 751, pu₁=pu₀ is assigned, and the number of the components subjected to mutation is CC=[rand(1)*npu]: the mutation component count variable cc₀=1 is initialized;
at step 752, if cc₀>CC, return is made to call the original steps (those calling the step 75 are: step 734, step 741, and step 742) of step 75, and otherwise, step 753 is performed;
at step 753, the first component to be mutated is nc₀=[rand(1)*npu], and the second component is nc₁=nc₀;
at step 754, it is determined whether nc₁=nc₀ is present: if yes, step 755 is performed, and if not, step 756 is performed;
at step 755, nc₁=[rand(1)*npu] and return to step 754;
at step 756, pu₁(nc₁)=pu₀(nc₀) and pu₁(nc₀)=pu₀(nc₁) are updated; and cc₀=cc₀+1 is updated: step 752 is repeated;
at step 76, the chromosome obtained by mutation operation is decoded and the corresponding placement path length is calculated: if it is superior to the result prior to mutation operation, it is substituted into the chromosome population, which comprises the following specific operations;
at step 761, with u=u₀ as input, step 4 is performed to generate an output containing the corresponding placement path optimization result and the placement path length DT, and D₂=DT is assigned;
at step 762, it is determined whether D₂<D(w₀) is present: if yes, the chromosome population U{w₀}=u₀ is updated, and D(w₀)=D₂ is updated: if not, no processing is performed: im=im+1 is updated and step 54 is repeated:

Other steps and parameters are the same as embodiments 1 to 7.

Embodiment 9: the difference of this embodiment from embodiments 1 to 8 is that: the specific process of outputting the optimal placement path optimization result in step 8 comprises the following steps:
at step 81, based on the optimal solution index wb, the optimal chromosome u=U {wb} is obtained;
at step 82, with u as input, step 4 is performed to generate an output containing the optimal placement path optimization result; the optimal placement point distribution result is PAb=PA and the optimal placement sequence result is PSb=PS;
at step 83, the surface mount machine performs mount production based on the optimal placement path optimization result.

Other steps and parameters are the same as the embodiments 1 to 8.

The following examples are used to verify the beneficial effects of the present disclosure.

### Example 1

This example provides a placement path optimization method of a surface mount machine based on a row-column grouping genetic algorithm, which is performed in the following steps.

A placement path optimization process of a surface mount machine with a 6-sucking-rod gantry type surface mount carrier is considered.

The circuit board production data to be imported is listed in Table 1, where there is one type of component, totaling 100 placement points.

TABLE 1
Circuit board production data

| Placement point SN | X coordinate (mm) | Y coordinate (mm) |
|---|---|---|
| 1 | −8.8 | 0 |
| 2 | −17.4 | 0 |
| 3 | −26 | 0 |
| 4 | −34.6 | 0 |
| 5 | −43.2 | 0 |
| 6 | −51.8 | 0 |
| 7 | −60.4 | 0 |
| 8 | −69 | 0 |
| 9 | −77.6 | 0 |
| 10 | −86.2 | 0 |
| 11 | −94.8 | 0 |
| 12 | −103.4 | 0 |
| 13 | −112 | 0 |
| 14 | −120.6 | 0 |
| 15 | −129.2 | 0 |
| 16 | −137.8 | 0 |
| 17 | −4.5 | 8.2 |
| 18 | −21.7 | 8.2 |
| 19 | −38.9 | 8.2 |
| 20 | −56.1 | 8.2 |
| 21 | −73.3 | 8.2 |
| 22 | −90.5 | 8.2 |
| 23 | −107.7 | 8.2 |
| 24 | −124.9 | 8.2 |
| 25 | −142.1 | 8.2 |
| 26 | −8.8 | 16.4 |
| 27 | −17.4 | 16.4 |
| 28 | −26 | 16.4 |
| 29 | −34.6 | 16.4 |
| 30 | −43.2 | 16.4 |
| 31 | −51.8 | 16.4 |
| 32 | −60.4 | 16.4 |
| 33 | −69 | 16.4 |
| 34 | −77.6 | 16.4 |
| 35 | −86.2 | 16.4 |
| 36 | −94.8 | 16.4 |
| 37 | −103.4 | 16.4 |
| 38 | −112 | 16.4 |
| 39 | −120.6 | 16.4 |
| 40 | −129.2 | 16.4 |
| 41 | −137.8 | 16.4 |
| 42 | −4.5 | 24.6 |
| 43 | −21.7 | 24.6 |
| 44 | −38.9 | 24.6 |
| 45 | −56.1 | 24.6 |
| 46 | −73.3 | 24.6 |
| 47 | −90.5 | 24.6 |
| 48 | −107.7 | 24.6 |
| 49 | −124.9 | 24.6 |
| 50 | −142.1 | 24.6 |
| 51 | −8.8 | 32.8 |
| 52 | −17.4 | 32.8 |
| 53 | −26 | 32.8 |
| 54 | −34.6 | 32.8 |
| 55 | −43.2 | 32.8 |
| 56 | −51.8 | 32.8 |
| 57 | −60.4 | 32.8 |
| 58 | −69 | 32.8 |
| 59 | −77.6 | 32.8 |
| 60 | −86.2 | 32.8 |
| 61 | −94.8 | 32.8 |
| 62 | −103.4 | 32.8 |
| 63 | −112 | 32.8 |
| 64 | −120.6 | 32.8 |
| 65 | −129.2 | 32.8 |
| 66 | −137.8 | 32.8 |
| 67 | −4.5 | 41 |
| 68 | −21.7 | 41 |
| 69 | −38.9 | 41 |
| 70 | −56.1 | 41 |
| 71 | −73.3 | 41 |
| 72 | −90.5 | 41 |
| 73 | −107.7 | 41 |
| 74 | −124.9 | 41 |
| 75 | −142.1 | 41 |
| 76 | −8.8 | 49.2 |
| 77 | −17.4 | 49.2 |
| 78 | −26 | 49.2 |
| 79 | −34.6 | 49.2 |
| 80 | −43.2 | 49.2 |
| 81 | −51.8 | 49.2 |
| 82 | −60.4 | 49.2 |
| 83 | −69 | 49.2 |
| 84 | −77.6 | 49.2 |
| 85 | −86.2 | 49.2 |
| 86 | −94.8 | 49.2 |
| 87 | −103.4 | 49.2 |
| 88 | −112 | 49.2 |
| 89 | −120.6 | 49.2 |
| 90 | −129.2 | 49.2 |
| 91 | −137.8 | 49.2 |
| 92 | −4.5 | 57.4 |
| 93 | −21.7 | 57.4 |
| 94 | −38.9 | 57.4 |
| 95 | −56.1 | 57.4 |
| 96 | −73.3 | 57.4 |
| 97 | −90.5 | 57.4 |
| 98 | −107.7 | 57.4 |
| 99 | −124.9 | 57.4 |
| 100 | −142.1 | 57.4 |

The placement points are grouped to obtain 8 dot array rows, and each of them contains the following placement point index:

$$AE \{ 1 \} ( 3 , : ) = [ \begin{matrix}16 & 15 & 14 & 13 & 12 & 11 & 10 & 9 & 8 & 7 & 6 & 5 & 4 & 3 & 2 & 1\end{matrix} ]$$

$$AE \{ 2 \} ( 3 , : ) = [ \begin{matrix}25 & 24 & 23 & 22 & 21 & 20 & 19 & 18 & 17\end{matrix} ]$$

$$AE \{ 3 \} ( 3 , : ) = [ \begin{matrix}41 & 40 & 39 & 38 & 37 & 36 & 35 & 34 & 33 & 32 & 31 & 30 & 29 & 28 & 27 & 26\end{matrix} ]$$

$$AE \{ 4 \} ( 3 , : ) = [ \begin{matrix}50 & 49 & 48 & 47 & 46 & 45 & 44 & 43 & 42\end{matrix} ]$$

$$AE \{ 5 \} ( 3 , : ) = [ \begin{matrix}66 & 65 & 64 & 63 & 62 & 61 & 60 & 59 & 58 & 57 & 56 & 55 & 54 & 53 & 52 & 51\end{matrix} ]$$

$$AE \{ 6 \} ( 3 , : ) = [ \begin{matrix}75 & 74 & 73 & 72 & 71 & 70 & 69 & 68 & 67\end{matrix} ]$$

$$AE \{ 7 \} ( 3 , : ) = [ \begin{matrix}91 & 90 & 89 & 88 & 87 & 86 & 85 & 84 & 83 & 82 & 81 & 80 & 79 & 78 & 77 & 76 ]\end{matrix}$$

$$AE \{ 8 \} ( 3 , : ) = [ \begin{matrix}100 & 99 & 98 & 97 & 96 & 95 & 94 & 93 & 92\end{matrix} ]$$

wherein the first, third, fifth, and seventh dot array rows belong to the first type of dot array rows, and the second, fourth, sixth, and eighth dot array rows belong to the second type of dot array rows. The optimal chromosome obtained by the present disclosure is:

$$u \{ 1 \} \{ 1 \} = [ \begin{matrix}1 & 3 & 7 & 9 & 12 & 15 & 2 & 5 & 6 & 10 & 13 & 16 & 11 & 14 & 8 & 4\end{matrix} ]$$

$$u \{ 1 \} \{ 2 \} = [ \begin{matrix}1 & 2 & 4 & 6 & 7 & 9 & 8 & 3 & 5\end{matrix} ]$$

$$u \{ 2 \} = [ \begin{matrix}25 & 24 & 13 & 11 & 10 & 20 & 8 & 27 & 6 & 21 & 13 & 4 & 9 & 18 & 17 & 7 & 28 & 15 & 5 & 14 & 16 & 1 & 12 & 22 & 3 & 19 & 2 & 26\end{matrix} ]$$

$$u \{ 3 \} = [ \begin{matrix}2 & 4 & 1 & 3 & 6 & 5\end{matrix} ]$$

The optimal chromosome is decoded to obtain the corresponding dot array row distribution result PL and the placement point column distribution result PM:

$$PL = [ \begin{matrix}1 & 1 & 1 & 1 & 1 & 1 \\ 3 & 3 & 3 & 3 & 3 & 3 \\ 5 & 5 & 5 & 5 & 5 & 5 \\ 7 & 7 & 7 & 7 & 7 & 7 \\ 1 & 1 & 1 & 1 & 1 & 1 \\ 3 & 3 & 3 & 3 & 3 & 3 \\ 5 & 5 & 5 & 5 & 5 & 5 \\ 7 & 7 & 7 & 7 & 7 & 7 \\ 2 & 2 & 2 & 2 & 2 & 2 \\ 4 & 4 & 4 & 4 & 4 & 4 \\ 6 & 6 & 6 & 6 & 6 & 6 \\ 8 & 8 & 8 & 8 & 8 & 8 \\ 1 & 1 & 1 & 1 & 2 & 2 \\ 2 & 3 & 3 & 3 & 3 & 4 \\ 4 & 4 & 5 & 5 & 5 & 5 \\ 6 & 6 & 6 & 7 & 7 & 7 \\ 7 & 8 & 8 & 8 & 9 & 9\end{matrix} ] PM = [ \begin{matrix}1 & 3 & 7 & 9 & 12 & 15 \\ 1 & 3 & 7 & 9 & 12 & 15 \\ 1 & 3 & 7 & 9 & 12 & 15 \\ 1 & 3 & 7 & 9 & 12 & 15 \\ 2 & 5 & 6 & 10 & 13 & 16 \\ 2 & 5 & 6 & 10 & 13 & 16 \\ 2 & 5 & 6 & 10 & 13 & 16 \\ 2 & 5 & 6 & 10 & 13 & 16 \\ 1 & 2 & 4 & 6 & 7 & 9 \\ 1 & 2 & 4 & 6 & 7 & 9 \\ 1 & 2 & 4 & 6 & 7 & 9 \\ 1 & 2 & 4 & 6 & 7 & 9 \\ 3 & 4 & 5 & 11 & 8 & 14 \\ 3 & 4 & 8 & 11 & 14 & 8 \\ 4 & 8 & 11 & 5 & 14 & 8 \\ 4 & 8 & 3 & 5 & 14 & 8 \\ 3 & 5 & 11 & 8 & 0 & 0\end{matrix} ]$$

Based on PL. PM, and AN, the following placement point distribution result PA and the placement sequence result PS are obtained:

$$PA = [ \begin{matrix}16 & 14 & 10 & 8 & 5 & 2 \\ 41 & 39 & 35 & 33 & 30 & 27 \\ 66 & 64 & 60 & 58 & 55 & 52 \\ 91 & 89 & 85 & 83 & 80 & 77 \\ 15 & 12 & 11 & 7 & 4 & 1 \\ 40 & 37 & 36 & 32 & 29 & 26 \\ 65 & 62 & 61 & 57 & 54 & 51 \\ 90 & 87 & 86 & 82 & 79 & 76 \\ 25 & 24 & 22 & 20 & 19 & 17 \\ 50 & 49 & 47 & 45 & 44 & 42 \\ 75 & 74 & 72 & 70 & 69 & 67 \\ 100 & 99 & 97 & 95 & 94 & 92 \\ 23 & 13 & 21 & 6 & 9 & 3 \\ 48 & 38 & 34 & 31 & 28 & 18 \\ 63 & 59 & 56 & 46 & 53 & 43 \\ 88 & 84 & 73 & 71 & 78 & 68 \\ 98 & 96 & 81 & 93 & 0 & 0\end{matrix} ] PS = [ \begin{matrix}6 & 5 & 4 & 2 & 3 & 1 \\ 6 & 5 & 4 & 2 & 3 & 1 \\ 6 & 5 & 4 & 2 & 3 & 1 \\ 6 & 5 & 4 & 2 & 3 & 1 \\ 6 & 3 & 5 & 4 & 2 & 1 \\ 6 & 3 & 5 & 4 & 2 & 1 \\ 6 & 3 & 5 & 4 & 2 & 1 \\ 6 & 3 & 5 & 4 & 2 & 1 \\ 5 & 2 & 6 & 3 & 4 & 1 \\ 5 & 2 & 6 & 3 & 4 & 1 \\ 5 & 2 & 6 & 3 & 4 & 1 \\ 5 & 2 & 6 & 3 & 4 & 1 \\ 5 & 6 & 2 & 4 & 3 & 1 \\ 6 & 5 & 2 & 4 & 3 & 1 \\ 6 & 4 & 5 & 1 & 3 & 2 \\ 6 & 3 & 4 & 5 & 1 & 2 \\ 3 & 4 & 1 & 2 & 5 & 6\end{matrix} ]$$

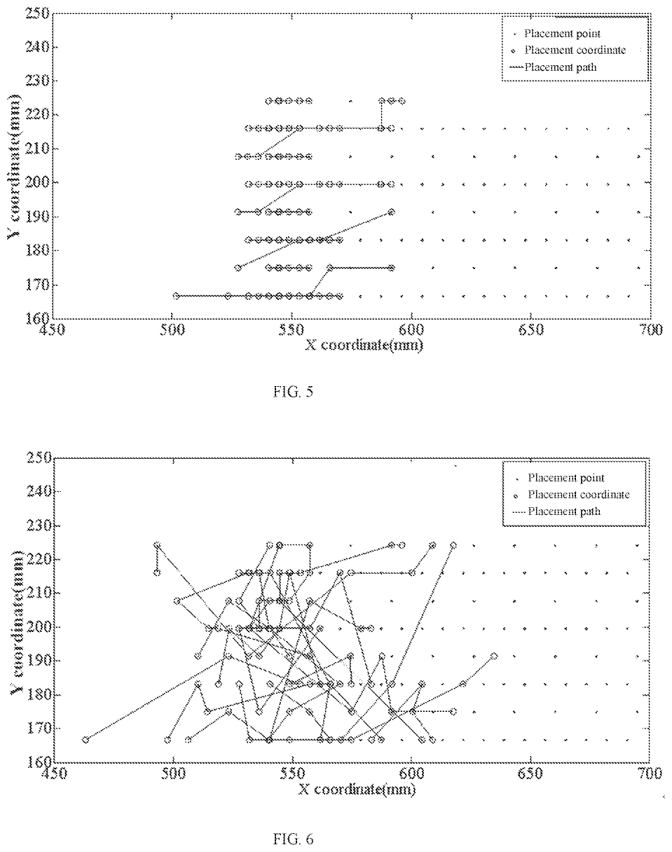

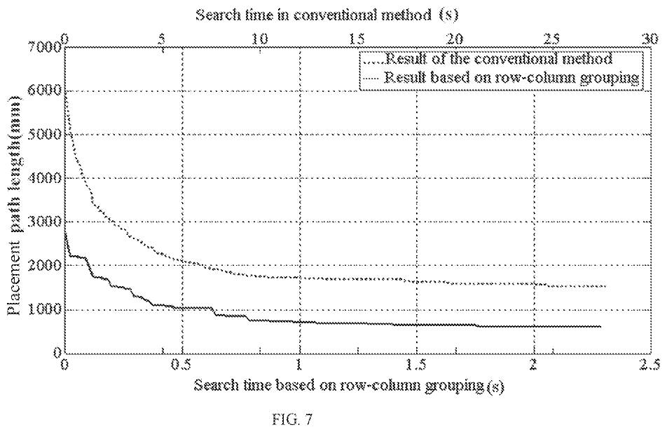

The above placement path optimization result is as shown in FIG. 5. The optimal placement path length is DT₁=603 mm and the calculation time for the result is TC₁=2.3s. In comparison, the example placement path obtained by the invention of the patent number 202010387801.3 is as shown in FIG. 6 and the corresponding placement path length is DT₀=1533 mm, and the calculation time for the result is TC₀=27.7s. The converging process of the placement path lengths corresponding to the two methods is as shown in FIG. 7. In this embodiment, the placement path can be improved as 100%*(DT₁−DT₀)/DT₀=60.7% in the present disclosure, with the search efficiency increased TC₀/TC₁=12.1 folds.

The present disclosure may have other embodiments and those skilled in the art can make various changes and variations to the present disclosure without departing from the spirit and essence of the present disclosure, but these changes and variations shall fall within the scope of protection of the claims appended to the specification.

What is claimed is:

1. A placement path optimization method of a surface mount machine based on a row-column grouping genetic algorithm, comprising the following process:
at step 1, obtaining a surface mount machine parameter and a circuit board production data;
at step 2, grouping placement points in a row to obtain dot array rows;
at step 3, encoding the row grouping results of the placement points to generate a chromosome population;
at step 4, decoding the chromosomes to obtain column grouping results of the placement points within the dot array rows, converting the column grouping results into placement path optimization results, calculating the placement path lengths, and outputting them;
at step 5, setting parameters and loop conditions for the genetic algorithm;
at step 6, based on a crossover operator, operating each chromosome and updating the placement path optimization result by comparison and selection;
at step 7, based on a mutation operator, operating each chromosome and updating the placement path optimization result by comparison and selection;
at step 8, outputting the optimal placement path optimization result.

2. The placement path optimization method of claim 1, wherein the specific process of obtaining the surface mount machine parameter and the circuit board production data in step 1 comprises the following steps:
at step 11, the surface mount machine parameter is obtained: the surface mount machine parameter comprises a total number H of suction heads, and an index of the suction heads in a sequence of increasing along X axis is numbered as hϵ[1, . . . , H], and a spacing between the suction heads is DI;
at step 12, the circuit board production data is obtained; the circuit board production data comprises a total number P of placement points, a sequence number of each placement point is pϵ[1, . . . , P], an array xyn₀ with a row number 3 and a column number P is initialized, the first two rows of the array store the coordinate of each placement point, the third row stores placement point number, and the X coordinate and Y coordinate of the P-th placement point are xyn₀(1,p) and xyn₀(2,p), where its placement point number is xyn₀(3,p)=p;
at step 13, each placement point is sorted in an increasing sequence of Y coordinates: i₀=sort(xyn₀(2,:)), where sort performs sorting on components in the array in an increasing sequence and returns an index of the sorted components in the original array, xyn₀=xyn₀(:,i₀);
“:” represents obtaining all values of this dimension in auto increment manner, and xyn₀(2,:) represents obtaining Y coordinates of all placement points, which are described below;
“1:1: P” represents an array increased with an increment of 1 from the start amount 1 to the end amount P, i.e. [1, . . . , P], “P:−1:1” represents an array increased with an increment of −1 from the start amount P to 1, i.e. [P,P−1, . . . , 1]: since the auto increment (increment 1) search is often used, 1:1:P is simplified as 1:P: when indexing is performed on the array, if the start amount is 1 and the end amount is just the number of the components in the dimension, xyn₀(2,1:P) is further simplified as xyn₀(2,:);
xyn₀(:,i₀) represents obtaining each column in the xyn₀ in the sequence of the array i₀, xyn₀=xyn₀(:,i₀) refers to re-storing xyn₀(:,i₀) into xyn₀ so as to re-sort each column in xyn₀ based on the array i₀;
notes: the sort result is described; if the original array before sorting is o₁=[2 3 1], the results of the array sorted in increasing sequence are o₂=[1 2 3], and thus the sequence of each component of o₂ in o₁ is o₃=sort(o₁)=[3 1 2], namely, o₂=o₁(o₃) is always established;
at step 14, a total number of PAP cycles is K=[P/H], where the symbol [ ] refers to performing up-rounding on the value therein, and a number of suction heads performing mounting in the last period is H₁=P−(K−1)*H;
wherein * represents a multiplication sign.

3. The placement path optimization method of claim 2, wherein the specific process of grouping placement points in a row to obtain the dot array rows in step 2 comprises:
at step 21, xyn₁=xyn₀ is assigned: the boundary layer thickness ab=2 of the placement points identified as a same dot array row is initialized: the count variable of the dot array rows is initialized l=0, the count variable of the dot array row type N=0, and the length array of the dot array row is M₁=[ ];
at step 22, it is determined whether xyn₁ is an empty array: if yes, it indicates all placement points have been grouped, and the total number of dot array rows L=l, step 3 is performed and otherwise, step 23 is performed;
at step 23, in the current ungrouped placement points, a placement point number forming the dot array rows with the placement point with the minimum Y coordinate is obtained as i₁=find(xyn₁(2,:)<ab+xyn₁(2,1)), and step 24 is performed;
wherein find represents a sequence number of the components satisfying the condition in the parentheses in the array in the parentheses after find: xyn₁(2,:) represents the Y coordinates of all placement points: xyn₁(2,1) represents the Y coordinate a first placement point;
at step 24, the count variable l=l+1 is updated: the meta array AE{l}=xyn₁(:,i₁) is initialized and assigned; each placement point is sorted in an increasing sequence of X coordinates, namely, i₀=sort(AE{l}(1,:)) and AE{l}=AE{l}(:,i₀); information xyn₁(:,i₁)=[ ] of the placement points grouped is cleared; step 25 is performed;
notes: the array with the braces { } as index mark is referred to as meta array;
wherein xyn₁(:,i₁) represents obtaining each column in xyn₁ in a sequence of the array i₁, AE{l}=xyn₁(:,i₁) stores information of each placement point in the l-th dot array row; AE{l} (1,:) represents the information of the X coordinate of each placement point in the l-th dot array row;
AE{l}(:,i₀) represents obtaining each column in AE{l} in a sequence of the array i₀, and AE{l}=AE{l}(:,i₀) refers to re-storing AE{l}(:,i₀) into AE{l}, so as to re-sort each column in AE{l} based on the array i₀;
at step 25, it is determined whether N=0 is present, if yes, step 26 is performed and if not, step 27 is performed;
at step 26, the count variable N=1 is updated to obtain the current dot array row length as M₀=col(AE{l}), wherein col represents obtaining a number of columns in the array in the parentheses after col and the dot array row length array M₁=[M₁ M₀] is updated; a distance AX{N}=AE{l}(1,:)−AE{l}(1,1) between each point and the first point in the current dot array row is calculated: the meta array AL{N}=l is initialized and assigned to store a dot array row index contained in each dot array row type: step 22 is repeated;
notes: AE{l}(1,1) represents the X coordinate of the first placement point in the l-th dot array row; M₁=[M₁ M₀] represents adding a new component M₀ to the end of the current M₁ array;
at step 27, a dot array row type to which the current dot array row belongs is divided;
at step 271, the count variable n=1 of the dot array row type is initialized;
at step 272, if n>N, it indicates that one traversal has been completed for the divided dot array row type, and step 22 is repeated and otherwise, step 273 is performed;
at step 273, the current dot array row length M₀=col(AE{l}) is obtained; it is determined whether M₁(n)=M₀ is present: if yes, the distance ax=AE{l}(1,:)−AE{l}(1,1) between each point and the first point in the current dot array row is calculated, and step 274 is performed and otherwise, step 275 is performed;
wherein M₁(n) represents the dot array row length in the n-th dot array row type;
at step 274, ba=sum(|AX{n}−ax|)/M₀ is assigned, wherein the symbol ∥ represents an absolute value of each value therein, and sum represents performing summing for the array in the parentheses after sum: it is determined whether ab>ba is present, and if yes, it indicates that the current dot array row belongs to the n-th type of dot array rows, the metal array AL{n}=[AL{n}l] is updated, n=N+1 is assigned, and step 272 is repeated and otherwise, step 275 is performed;
wherein AL{n} represents each dot array row index in the n-th dot array row type; AL{n}=[AL{n}l] represents adding a new component l to the end of AL{n}, namely, adding the l-th dot array row in the n-th dot array type;
at step 275, it is determined whether n=N is present: if yes, it indicates that the current dot array row does not belong to any divided dot array row type, and step 276 is performed, and otherwise, the count variable n=n+1 is updated and step 272 is repeated;
at step 276, the count variable N=N+1 is updated, the dot array row length array M₁=[M₁ M₀] is updated, the arrays AX{N}=ax and AL{N}=l are initialized and assigned: n=N+1 is assigned and step 272 is repeated.

4. The placement path optimization method of claim 3, wherein the specific process of performing chromosome coding on the row grouping result of the placement points to obtain the chromosome population in step 3 comprises:
at step 31, the number of the chromosome populations is initialized to W=40; with w as chromosome index, the chromosome population U{w}=[U{1}, . . . , U{W}] is initialized to empty array: the array D with a row number 1 and a column number W with all components being zero is initialized to store a placement path length corresponding to each chromosome: the maximum variable inf=100000 is initialized; the optimal placement path length DTb=inf is initialized; the number of daughter chromosomes is initialized to V=3; with v as daughter chromosome index, each daughter chromosome u{v}=[u{1}, . . . , u{V} ] is initialized to empty array: the count w=1 of the number of the chromosome populations is initialized;
at step 32, the number of placement points to be mounted across each dot array row is obtained, which comprises the following specific operations;
at step 321, the dot array row type count n=1 is initialized: the array AC with a row number 1 and a column number N with all components being zero is initialized to store the number of the dot array rows contained in each dot array row type: the array K₁ with a row number 1 and a column number N with all components being zero is initialized to store the number of the PAP cycles for filling the placement points in each type of dot array rows: NG=0 is initialized and assigned to store gene loca in the chromosome; the array aj with a row number 1 and a column number L with all components being zero is initialized to store the number of placement points mounted across row in each dot array row: NJ=0 is initialized and assigned to store a total number of placement points to be mounted across row;
at step 322, if n>N, NG=NG+NJ+H is updated and step 33 is performed, and otherwise, step 323 is performed;
at step 323, K₁(n)=└M₁(n)/H┘ is calculated wherein the symbol └ ┘ represents performing down-rounding for the value therein;
wherein K₁(n) represents a number of PAP cycles required to complete mounting for one n-th type of dot array rows;
at step 324, the number of placement points to be mounted across row in the current type of dot array rows is nj=M₁(n)−H*K₁(n): AC(n)=col(AL{n}), NJ=NJ+AC(n)*nj, NG=NG+M₁(n) are updated; the count variable l₁=1 is initialized;
wherein AC(n) represents the number of dot array rows contained in the n-th type of dot array rows;
at step 325, it is determined whether l₁>AC(n) is present; if yes, the count variable n=n+1 is updated and step 322 is repeated, and otherwise, step 326 is performed;
at step 326, a dot array row sequence number l=AL{N}(l₁) is obtained and aj(l)=nj is assigned; the count variable l₁=l₁+1 is updated, and step 325 is repeated;
notes: l=AL{N}(l₁) represents an index of the l₁-th dot array row in the N-type of dot array rows; aj(l) represents the number of placement points to be mounted across row in the dot array row with the index l;
at step 33, the daughter chromosomes u{1} of the placement point distribution sequence of various types of dot array rows are obtained, which includes the following specific operations;
at step 331, corresponding to each dot array row type nϵ[1, . . . , N], the meta array pa{n}ϵ[pa{1}, . . . , pa{N}] with a row number M₁(n) and a column number 1 with all components being zero is initialized to store the placement point distribution sequence of each type of dot array rows, wherein pa{n} is referred to as the distribution sequence chromosomes of the n-type of dot array rows: the dot array row type count n=1 is initialized;
at step 332, if n>N, step 34 is performed and otherwise, step 333 is performed;
at step 333, pa{n}=randperm([1, . . . , M₁(n)]), wherein randperm represents generating a random permutation of the array in the parentheses after randperm: u{1}{n}=pa{n} is assigned;
the count variable n=n+1 is updated and step 332 is repeated;
notes: u is a two-dimensional meta array, wherein u{1} is the first meta array in u, u{1}{n} is the n-th array in u{1}, namely, the distribution sequence chromosomes of the n-th type of dot array rows;
at step 34, the placement sequence daughter chromosomes u{2}=randperm([1, . . . , NJ]) across dot array row are obtained: step 35 is performed;
at step 35, the daughter chromosomes u{3}=randperm([1, . . . , H]) selected by the suction heads in the last period are obtained: step 36 is performed;
at step 36, U{w}=u is assigned: with u as input, step 4 is performed to obtain an output containing the corresponding placement path optimization result and placement path length DT, D(w)=DT; step 37 is performed;
wherein u represents one chromosome, i.e. one set of daughter chromosomes, U{w}=u represents that u is stored as the w-th chromosome in the chromosome population; DT represents the placement path length corresponding to the chromosome u, D(w)=DT represents the placement path length DT corresponding to the w-th chromosome in the chromosome population;
at step 37, it is determined whether DTb>D(w): if yes, the optimal placement path length DTb=D(w) is updated, and the optimal solution index wb=w is updated, and otherwise, no processing is performed: step 38 is performed;
at step 38, the count variable w=w+1 is updated, and if w>W, step 5 is performed and otherwise, step 33 is performed.

5. The placement path optimization method of claim 4, wherein the specific process of performing chromosome decoding to obtain a column grouping result of the placement points in the dot array rows and converting the column grouping result into a placement path optimization result, and calculating and outputting a placement path length in step 4 comprises:
at step 41, initialization is performed, which comprises the following specific operations;
at step 411, the placement path length DT=0, the PAP cycle count k=0 and the sucking-rod traversed array ah=[1, . . . , H] are initialized and assigned;
at step 412, the two-dimensional array PA with a row number K and a column number H with all components being zero is initialized to store a placement point distribution result, wherein the component PA(k,h) is used to store a placement point number mounted by the h-th suction head in the k-th PAP cycle: the two-dimensional array PS with a row number K and a column number H with all components being zero is initialized to store the placement sequence result, wherein the component PS(k,s) is used to store the s-th suction head number performing mounting in the k-th PAP cycle: the two-dimensional array PL with a row number K and a column number H with all components being 1 is initialized, wherein the component PL(k,h) is used to store the dot array row sequence number mounted by the h-th suction head in the k-th PAP cycle: the two-dimensional array PM with a row number K and a column number H with all components being 1 is initialized, wherein the component PM(k,h) is used to store a sequence number, in the dot array rows, of the placement point mounted by the h-th suction head in the k-th PAP cycle: the two-dimensional array PX with a row number K and a column number H with all components being inf is initialized, wherein the component PX(k,h) is used to store the X coordinate of the surface mount carrier used by the h-th suction head for mounting in the k-th PAP cycle; the two-dimensional array PY with a row number K and a column number H with all components being inf is initialized, wherein the component PY(k,h) is used to store the Y coordinate of the surface mount carrier used by the h-th suction head for mounting in the k-th PAP cycle; the two-dimensional array TJ with a row number L and a column number H with all components being zero is initialized, wherein the component TJ(l,h) is used to store the sequence number, in the l-th dot array row, of the h-th placement point to be mounted across row in the l-th dot array row;
at step 413, L₁=L+1 is assigned: the two-dimensional array AJ with a row number L₁ and a column number 1 with all components being zero is initialized to accumulate the number of the placement points to be mounted across row: AJ(L₁)=NJ+1 is assigned: the dot array row count variable l=2 is initialized;
wherein AJ(L₁) represents an upper limit of the number of the cross-row placement points;
at step 414, if l>L, the dot array row type count n=1 is initialized, and step 42 is performed and otherwise, step 415 is performed;
at step 415, AJ(l)=AJ(l−1)+aj(l−1); the count variable l=l+1 is updated, and step 414 is repeated;
wherein AJ(l) represents the number of cross-row placement points distributed when row-by-row distribution is performed to the I-th dot array row;
at step 42, column grouping is performed on the placement points in the dot array row filling up the full period, which comprises the following specific operations;
at step 421, if n>N, step 43 is performed and otherwise, step 422 is performed;
at step 422, the temporary chromosome q₀=u{1}{n} is assigned; and the count variable k₁=1 is initialized;
at step 423, it is determined whether k₁>K₁(n) is present: if yes, the count variable l₂=1 is initialized, and step 427 is performed and if not, step 424 is performed;
at step 424, ap=q₀(ah) is assigned, and q₀(ah)=[ ] is updated: the count variable l₁=1 is initialized;
wherein q₀=u{1}{n} represents that q₀ stores the distribution sequence chromosomes of the n-th type of dot array rows, q₀(ah) represents an array formed by the first to H-th components in the distribution sequence chromosomes of the n-th type of dot array rows;
at step 425, it is determined whether l₁>AC(n) is present: if yes, the count variable k₁=k₁+1 is updated, and step 423 is repeated: if not, step 426 is repeated;
at step 426, the PAP cycle count k=k+1 is updated: the dot array row sequence number l=AL{N}(l₁) is obtained; PL(k,:)=PL(k,:)*l, PM(k,:)=ap, PX(k,:)=AE{l}(1,ap)−(ah−1)*DI, PY(k,:)=AE{l}(2,ap), and PA(k,:)=AE{l}(3,ap) are assigned: the count variable l₁=l₁+1 is updated, and step 425 is repeated;
wherein PL(k,:) represents a dot array row sequence number mounted by each suction head in the k-th PAP cycle: PM(k,:) represents a sequence number, in the dot array row, of the placement point mounted by each suction head in the k-th PAP cycle: PX(k,:) represents the X coordinate of the surface mount carrier when each suction head performs mounting in the k-th PAP cycle: PY(k,:) represents the Y coordinate of the surface mount carrier when each suction head performs mounting in the k-th PAP cycle: PA(k,:) represents the placement point number mounted by each suction head in the k-th PAP cycle: AE{l}(1,ap) represents the X coordinate of the placement point obtained in the I-th dot array row in the sequence of the array ap; AE{l}(2,ap) represents the Y coordinate of the placement point obtained in the l-th dot array row in the sequence of the array up; AE{l}(3,ap) represents the placement point number obtained in the l-th dot array row in the sequence of the array ap;
at step 427, it is determined whether 12>AC(n) is present: if yes, the count variable n=n+1 is updated, and step 421 is repeated, and if not, step 428 is performed;
at step 428, the dot array row sequence number l=AL{N} (l₂) is obtained; TJ(1,1:aj(l))=q₀ is assigned: the count variable l₂=l₂+1 is updated, and step 427 is repeated;
wherein AL{N}(l₂) represents an index of the l₂-th dot array row in the N-th type of dot array rows; TJ(1,1:aj(l)) represents the sequence number, in the l-th dot array row, of the first to aj(l)-th placement points to be mounted across row in the l-th dot array row;
at step 43, column grouping is performed on the placement points to be mounted across row, which comprises the following specific operations;
at step 431, the temporary chromosome q₁=u{2} is assigned: the count variable l₀=1 of the first dot array row being distributed is initialized: the number of the undistributed placement points in the dot array row being distributed is g₀=aj(1): a total number of PAP cycles for cross-row mounting is K₂=└NJ/H┘: the PAP cycle count k₂=1 for cross-row mounting is initialized;
wherein aj(1) represents the number of placement points to be mounted across row in the first dot array row;
at step 432, it is determined whether k₂>K₂ is present: if yes, step 44 is performed and if not, the placement point accumulated variable g₁=g₀ is assigned, and the search count variable l₁=l₀+1 of to-be-distributed dot array row is initialized, and step 433 is performed;
at step 433, it is determined whether l₁>L is present: if yes, step 435 is performed and if not, step 434 is performed;
at step 434, g₁=g₁+aj(l₁) is updated: it is determined whether g₁>H: if yes, it indicates that the currently-accumulated placement points are sufficient to fill up one PAP cycle, l₀=l₁ and l₁=L+1 are updated, and step 433 is repeated, and otherwise, l₁=l₁+1 is updated, and step 433 is performed;
wherein aj(l₁) represents the number of placement points to be mounted across row in the l₁-th dot array row;
at step 435, decoding is performed based on q₁ to only retain H placement points satisfying conditions so as to fill up one PAP cycle: i₂=find(q₁<AJ(l₀+1)), i₃=find(q₁(l₂)>AJ(l₀)) and the number of the remaining placement points g₀=g₁−H, g₂=aj(l₁)−g₀+1 is assigned, i₄=3(g₂:aj(l₀)) is assigned, i₂(i₄)=[ ] is updated, the chromosome segments to be distributed in the current period are pq=q₁(i₂), q₁(i₂)=[ ] is updated: the PAP cycle count k=k+1 is updated; the suction head count variable h=1 is assigned;
wherein AJ(l₀+1) represents the number of the cross-row placement points distributed when row-by-row distribution is performed to the (l₀+1)-th dot array row: AJ(l₀) represents the number of the cross-row placement points distributed when row-by-row distribution is performed to the l₀-th dot array row: q₁(i₂) represents components obtained from the temporary chromosomes q₁ in the sequence of the array i₂; aj(l₀) represents the number of placement points to be mounted across row in the dot array row with the index of l₀: i₂ is a temporary variable representing an component sequence less than AJ(l₀+1) in q₁; i₃ is a temporary variable representing an component sequence greater than AJ(l₀) in q₁(i₂): i₄=i₃(g₂:aj(l₀)) represents the g₂-th to aj(l₀)-th component in i₃; and i₂(i₄) represents the components obtained from i₂ in the sequence of the array i₄;
at step 436, it is determined whether h>H is present; if yes, the count variable k₂=k₂+1 is updated, and step 432 is repeated, and if not, step 437 is performed;
at step 437, i₅=find(AJ≥pq(h)) is assigned, the dot array row number where the current placement point is located is l=i₅(1)−1, the sequence number of the placement point in the dot array row is ap=TJ(l,pq(h)−AJ(₀)); PL(k,h)=l, PM(k,h)=ap, PX(k,h)=AE{l}(1,ap)−(h−1)*DI, PY(k,h)=AE{l}(2,ap), and PA(k,h)=AE{l}(3,ap) are assigned; the count variable h=h+1 is updated and step 436 is repeated;
wherein is represents the component sequence number no less than pq(h) in AJ; pq(h) represents the h-th component in the chromosome segment pq;
at step 44, column grouping is performed on the placement points in the last period, which comprises the following specific operations;
at step 441, if H₁>0, it indicates that there is an idle suction head in the last period, and step 442 is performed, and otherwise, step 45 is performed;
at step 442, the temporary chromosome q₂=u{3}(1:H;) is assigned: sorting is performed on the components in q₂ in an increasing sequence, namely, i₀=sort(q₂) and q₂=q₂(i₀); PL(K,:)=PL(K,:)*L₁ is assigned; the suction head count variable s=1 is assigned;
wherein u{3}(1:H;) represents the suction heads select the first to H₁-th component in the daughter chromosomes in the last period;
at step 443, it is determined whether s>H₁; if yes, step 45 is performed and if not, step 444 is performed;
at step 444, i₆=find(AJ≥q₁(s)) is assigned: the dot array row number where the current placement point is located is l=i₆(1)−1, and the sequence number of the placement point in the dot array row is ap=TJ(l,q₁(s)−AJ(l));
wherein i₆ represents an component sequence number no less than q₁(s) in AJ; q₁(s) represents the s-th component in the temporary chromosome q₁; i₆(1) represents the first component sequence number no less than q₁(s) in AJ;
at step 445, the suction head number h=q₂(s) is obtained: PL(K,h)=l, PM(K,h)=ap, PX(K,h)=AE{l}(1,ap)−(h−1)*DI, PY(K,h)=AE{l}(2,ap), and PA(K,h)=AE{l}(3,ap) are assigned: the count variable s=s+1 is updated and step 443 is performed;
wherein q₂(s) represents the s-th component in the temporary chromosome q₂: PL(K,h) is used to store a dot array row sequence number mounted by the h-th suction head in the K-th PAP cycle: PM(K,h) is used to store the sequence number, in the dot array row, of the placement point mounted by the h-th suction head in the K-th PAP cycle: PX(K,h) is used to store the X coordinate of the surface mount carrier when the h-th suck rod performs mounting in the K-th PAP cycle; PY(K,h) is used to store the Y coordinate of the surface mount carrier when the h-th suck rod performs mounting in the K-th PAP cycle; PA(K,h) is used to store the placement point number mounted by the h-th suction head in the K-th PAP cycle;
at step 45, based on the column grouping result of the placement points, the placement path optimization result is obtained and the placement path length is calculated, which comprises the following specific operations;
at step 451, the PAP cycle count is k=1;
at step 452, if k>K, DT, PA, and PS are outputted to call the original steps of the step 4 and otherwise, step 453 is performed;
at step 453, firstly, based on an increasing sequence of X coordinates, the placement points of the current PAP cycle are sorted: i₇=sort(PX(k,:)), PX(k,:)=PX(k,i₇), PY(k,:)=PY(k,i₇), PL(k,:)=PL(k,i₇);
next, based on an increasing sequence of dot array row sequence numbers, each placement point is sorted again: i₈=sort(PL(k,:)), PX(k,:)=PX(k,i₈), PY(k,:)=PY(k,i₈), PL(k,:)=PL(k,i₈); the placement sequence result in the current PAP cycle is PS(k,:)=i₇(i₈);
wherein i₇ represents an index of each component in the original array after sorting is performed on the components in array PX(k,:) in an increasing sequence: PX(k,i₇) represents obtaining the X coordinate of the surface mount carrier in the K-th PAP cycle with i₇ as the suction head index: PY(k,i₇) represents obtaining the Y coordinate of the surface mount carrier in the K-th PAP cycle with i₇ as the suction head index: PL(k,i₇) represents obtaining the dot array row sequence number in the K-th PAP cycle with i₇ as the suction head index: is represents an index of each component in the original array after sorting is performed on the components in the array PL(k,:) in an increasing sequence: PX(k,i₈) represents the X coordinate of the surface mount carrier in the K-th PAP cycle with is as suction head index: PY(k,i₈) represents the Y coordinate of the surface mount carrier in the K-th PAP cycle with is as suction head index: PL(k,i₈) represents obtaining the dot array row sequence number in the K-th PAP cycle with is as the suction head index;
at step 454, the suction head count variable s=2 is assigned: if k=K, H₂=H₁; otherwise, H₂=H; step 455 is performed;
at step 455, if s>H₂, the count variable k=k+1 is updated, and step 452 is repeated and otherwise, step 456 is performed;
at step 456, a Chebyshev distance between the current mount coordinate and a previous mount coordinate is dt=max(|PX(k,s)−PX(k,s−1)|,|PY(k,s)−PY(k,s−1)|); the placement path length DT=DT+dt is updated: the count variable s=s+1 is updated, and step 455 is repeated;
wherein PX(k,s) is used to store the X coordinate of the surface mount carrier when the s-th suction head performs mounting in the k-th PAP cycle; PY(k,s) is used to store the Y coordinate of the surface mount carrier when the s-th suction head performs mounting in the k-th PAP cycle.

6. The placement path optimization method of claim 5, wherein the specific process of setting the parameter and the cyclic condition of the genetic algorithm in step 5 comprises the following steps:
at step 1, the crossover probability RC=0.6 and the mutation probability RM=0.02 of the genetic algorithm are initialized: the upper limit IC=RC*W of the number of times of the crossover operation is calculated, the upper limitIM=RM*W*NG of the number of times of the mutation operation is calculated, the upper limit IT=2*[(NG)0.5] of the number of times of the non-improved search is calculated; wherein the symbol [ ] refers to performing up-rounding for the value therein: the non-improved search count variable it=0 is initialized;
at step 52, if it>IT, it indicates that the upper limit of number of times of the non-improved search is reached, and step 8 is performed; otherwise, the crossover operation count ic=1 is initialized, and step 53 is performed;
at step 53, if ic>IC, it indicates that the upper limit of number of times of the crossover operation is reached, the mutation operation count im=1 is initialized, and step 54 is performed, and otherwise, step 6 is performed;
at step 54, if im>IM, it indicates that the upper limit of the number of times the mutation operation is reached, step 55 is performed and otherwise, step 7 is performed;
at step 55, [db,wo]=min(D) is obtained, wherein min represents the minimum value of the array in the parentheses after min, db is the minimum placement path length obtained at present, wo is a chromosome index for achieving the optimal placement path: it is determined whether DTb>db is present; if yes, the optimal placement path length DTb=db is updated, and the optimal solution index wb=wo is updated, and the count variable it=0 is updated: if not, the count variable it=it+1 is updated and step 52 is repeated.

7. The placement path optimization method of claim 6, wherein the specific process of, based on the crossover operator, operating each chromosome and updating the placement path optimization result by comparison and selection in step 6 comprises the following steps:
at step 61, based on roulette wheel selection, two chromosomes subjected to crossover operation are selected, which comprises the following steps;
at step 611, the arrays E and SR with a row number 1 and a column number W with all components being zero are initialized: each chromosome wϵ[1, . . . , W} is traversed: E(w)=1/D(w) is assigned, the selection probability SR(w)=E(w)/sum(E) of each chromosome is assigned: the chromosome serial numbers w₀=0 and w₁=0 selected are initialized;
wherein E(w) is the reciprocal of D(w);
at step 612, it is determined whether w₀=w₁ is present: if yes, step 613 is performed and otherwise, the temporary chromosome population U₁{w₃}=[U₁]{1}, . . . , U₁{4}], U₁{1}=U{w₀}, U₁{2}=U{w₁}, U₁{3}=U{w₀}, U₁{4}=U{w₁} are initialized: the array DI with one row and four columns is initialized and D₁=[D(w₀) D(w₁) D(w₀) D(w₁)] is assigned and step 62 is performed;
wherein U₁{1} represents the first chromosome in the temporary chromosome population; U₁{2} represents the second chromosome in the temporary chromosome population: U₁{3} represents the third chromosome in the temporary chromosome population: U₁{4} represents the fourth chromosome in the temporary chromosome population: U{w₀} represents the w₀-th chromosome in the chromosome population: U{w₁} represents the w₁-th chromosome in the chromosome population; D(w₀) represents the placement path length corresponding to the wo-th chromosome in the chromosome population; D(w₁) represents the placement path length corresponding to the w₁-th chromosome in the chromosome population;
at step 613, the selection probabilities sr₀=rand(1) and sr₁=rand(1) are generated, wherein rand(1) refers to generating a random number between 0 and 1; the chromosome count variable w₂=1 is initialized and the probability accumulated variable sr=0 is initialized;
wherein rand(1) refers to generating a random number between 0 and 1;
at step 614, if w₂>W, the chromosome count variable w₂=1 is reset, and the probability accumulated variable sr=0 is cleared to zero, and step 616 is performed and otherwise, step 615 is performed;
at step 615, sr=sr+SR(w₂) is updated; it is determined whether sr<sr₀ is present: if yes, w₂=w₂+1 is updated and if not, w₀=w₂ is stored, and w₂=W+1 is assigned: step 614 is repeated;
wherein SR(w₂) represents the selection probability of the w₂-th chromosome;
at step 616, if w₂>W, step 612 is repeated and otherwise, step 617 is performed;
at step 617, sr=sr+SR(w₂) is updated; it is determined whether sr<sr₁ is present; if yes, w₂=w₂+1 is updated, and if not, w₁=w₂ is stored and w₂=W+1 is assigned: step 616 is repeated;
at step 62, if it≤[IT/4], step 63 is performed, and otherwise, step 64 is performed;
at step 63, in the two selected chromosomes, the crossover operation is performed on the placement point distribution sequence daughter chromosomes of each type of dot array rows, which comprises the following specific operations;
at step 631, the count variable n=1 of the dot array row type is initialized;
at step 632, if n>N, step 64 is performed and otherwise, step 633 is performed;
at step 633, two chromosome segments pu₀={3}{1}{n} and pu₁=U₁{4}{1}{n} to be operated are selected, and the chromosome segment length is npu=M₁(n);
wherein U₁ is a three-dimensional array, wherein U₁{3} represents the third chromosome in the temporary chromosome population, U₁{3}{1} represents obtaining the first daughter chromosome in U₁{3}, namely, the placement point distribution sequence daughter chromosome of each type of dot array rows, U₁{3}{1}{n} represents obtaining the placement point distribution sequence of the n-th type of dot array rows in the daughter chromosome U₁{3}{1}: U₁{4} represents the fourth chromosome in the temporary chromosome population, U₁{4}{1} represents obtaining the first daughter chromosome in U₁{4}, namely, the placement point distribution sequence daughter chromosome of each type of dot array rows, U₁{4}{1}{n} represents the placement point distribution sequence of the n-th type of dot array rows in the daughter chromosome U₁{4}{1};
at step 634, with pu₀, pu₁, and npu as input, step 65 is performed and pu₂ and pu₃ subjected to crossover operation are obtained from the output, and U₁{3}{1}{n}=pu₂ and U₁{4}{1}{n}=pu₃ are assigned: the count variable n=n+1 is updated, and step 632 is repeated;
at step 64, the crossover operation is performed on the cross-dot-array-row placement sequence daughter chromosome in the two selected chromosomes and the daughter chromosome selected by the suction head in the last period, which comprises the following specific operations;
at step 641, two chromosome segments pu₀=U₁{3}{2} and pu₁=U₁{4}{2} to be operated are obtained, the chromosome segment length is npu=NJ; with pu₀, pu₁, npu as input, step 65 is performed and pu₂ and pu₃ subjected to crossover operation are obtained from the output, and U₁{3}{2}=pu₂ and U₁{4}{2}=pu₃ are assigned: step 642 is performed;
wherein U₁{3} represents the third chromosome in the temporary chromosome population, U₁{3}{2} represents obtaining the second daughter chromosome in U₁{3}, namely, the cross-dot-array-row placement sequence daughter chromosome: U₁{4} represents the fourth daughter chromosome in the temporary chromosome population, U₁{4}{2} obtaining the second daughter chromosome in U₁{4}, namely, the cross-dot-array-row placement sequence daughter chromosome;
at step 642, two chromosome segments pu₀=U₁{3}{3} and pu₁=U₁{4}{3} to be operated are obtained, the chromosome segment length is npu=H: with pu₀, pu₁, npu as input, step 65 is performed and pu₂ and pu₃ subjected to crossover operation are obtained from the output, and U₁{3}{3}=pu₂ and U₁{4}{3}=pu₃ are assigned: step 643 is performed;
wherein U₁{3} represents the third chromosome in the temporary chromosome population, U₁{3}{3} represents obtaining the third daughter chromosome in U₁{3}, namely, the daughter chromosome selected by the suction head in the last period: U₁{4} represents the fourth chromosome in the temporary chromosome population, U₁{4}{3} represents obtaining the third daughter chromosome in U₁{4}, namely, the daughter chromosome selected by the suction head in the last period;
at step 643, step 66 is performed;
at step 65, the crossover operation is performed on the input two chromosome segments, which comprises the following specific operations;
at step 651, the number of the components crossed is nc₀=3: the start component number crossed is nc₁=[rand(1)*npu]: it is determined whether nc₀−1+nc₁>npu is present: if yes, the end component number crossed is nc₂=nc₁−nc₀+1: the component array to be operated is NC₀=nc₂:nc₁; if not, nc₂=nc₁+nc₀−1 and NC₀=nc₁:nc₂; and NC₁=NC₀, NC₂=NC₀, pu₂=pu₀, pu₃=pu₁: the component count variable cc₀=1 in the operation region is initialized, and the number of the components in the operation region is CC=nc₀;
at step 652, if cc₀>CC, step 654 is performed and otherwise, step 653 is performed;
at step 653, it is determined whether an component is equal to pu₂(NC₀(cc₀)) in the array pu₃(NC₁); if yes, the index of the component is in cc₁, and NC₀(cc₀)=[ ], NC₁(cc₁)=[ ], CC=CC−1 are updated: if not, cc₀=cc₀+1 is updated: step 652 is repeated;
at step 654, CC=numel(NC₁), wherein numel represents the number of components in the array in the parentheses after numel: it is determined whether CC=0 is present: if yes, step 657 is performed, and if not, the count variable cc₀=1 is initialized and step 655 is performed;
at step 655, if cc₀>CC, step 657 is performed, and otherwise, step 656 is performed;
at step 656, cc₁=find(pu₀=pu₃(NC₁(cc₀))), pu₂(cc₁)=pu₀(NC₀(cc₀)) is updated; cc₁=find(pu₁=pu₂(NC₀(cc₀))), pu₃(cc₁)=pu₁(NC₁(cc₀)) is updated; cc₀=cc₀+1 is updated: step 655 is repeated;
at step 657, pu₂(NC₂)=pu₁(NC₂) and pu₃(NC₂)=pu₀(NC₂); pu₂ and pu₃ are outputted to call the original steps of step 65;
at step 66, two chromosomes obtained by crossover operation are decoded, and the corresponding placement path length is calculated: if it is superior to the result prior to the crossover operation, it is substituted into the chromosome population, which comprises the following specific operations;
at step 661, with u=U₁{3} as input, step 4 is performed to generate an output containing the corresponding placement path optimization result and the placement path length DT, and D₁(3)=DT is assigned;
at step 662, with u=U₁{4} as input, step 4 is performed to generate an output containing the corresponding placement path optimization result and the placement path length DT, and D₁(4)=DT is assigned;
at step 663, i₀=sort(D₁), wherein the indexes of two minimum components in D₁ are w₄=i₀(1) and w₅=i₀(2);
at step 664, the chromosome populations U{w₀}=U₁{w₄} and U{w₁}=U₁ {w₅} are updated, D(w₀)=D₁(w₄) and D(w₁)=D₁(w₅) are updated: ic=ic+1 is updated, and step 53 is repeated.

8. The placement path optimization method of claim 7, wherein the specific process of, based on mutation operator, operating each chromosome and updating the placement path optimization result by comparison and selection in step 7 comprises:
at step 71, based on roulette wheel selection, a chromosome subjected to mutation operation is selected, which comprises the following specific operations;
at step 711, each wϵ[1, . . . , W} is traversed, E(w)=1/D(w) is assigned, the selection probability of each chromosome SR(w)=E(w)/sum(E) is assigned: the chromosome serial number selected is initialized to w₀=0;
at step 712, the selection probability sr₀=rand(1) is generated: the chromosome count variable w₂=1 is initialized, and the probability accumulated variable sr=0 is initialized;
at step 713, if w₂>W, step 715 is performed and otherwise, step 714 is performed;
at step 714, sr=sr+SR(w₂) is updated; it is determined whether sr<sr₀ is present: if yes, w₂=w₂+1 is updated, and if not, w₀=w₂ is stored, and w₂=W+1 is assigned: step 713 is repeated;
at step 715, the temporary chromosome u₀=U{w₀} is initialized; D₂=D(w₀) is initialized and assigned: step 72 is performed;
at step 72, if it≤└IT/4┘, step 73 is performed and otherwise, step 74 is performed;
at step 73, in the selected chromosomes, mutation operation is performed on the placement point distribution sequence daughter chromosomes of each type of dot array rows, which comprises the following specific operations;
at step 731, the count variable n=1 of the dot array row type is initialized;
at step 732, if n>N, step 74 is performed and otherwise, step 733 is performed;
at step 733, the chromosome segment pu₀=u₀{1}{n} to be operated is obtained, and the chromosome segment length is npu=M₁(n);
at step 734, with pu₀ and npu as input, step 75 is performed and pu₁ subjected to mutation operation is obtained from the output, and w₀{1}{n}=pu₁ is assigned; the count variable n=n+1 is updated and step 732 is repeated;
at step 74, mutation operation is performed on the cross-dot-array-row placement sequence daughter chromosome in the two selected chromosomes and the daughter chromosome selected by the suction head in the last period, which comprises the following specific operations;
at step 741, the chromosome segment pu₀=u₀{2} to be operated is obtained, and the chromosome segment length is npu=NJ; with pu₀ and npu as input, step 75 is performed, and pu₁ subjected to mutation operation is obtained from the output, and u₀{2}=pu₁ is assigned;
at step 742, the chromosome segment pu₀=u₀{3} to be operated is obtained, and the chromosome segment length is npu=H: with pu₀ and npu as input, step 75 is performed, and pu₁ subjected to mutation operation is obtained from the output, and u₀{4}=pu₁ is assigned;
at step 743, step 76 is performed;
at step 75, mutation operation is performed on the input chromosome segment, which comprises the following specific operations;
at step 751, pu₁=pu₀ is assigned, and the number of the components subjected to mutation is CC=[rand(1)*npu]: the mutation component count variable cc₀=1 is initialized;
at step 752, if cc₀>CC, return is made to call the original steps of step 75, and otherwise, step 753 is performed;
at step 753, the first component to be mutated is nc₀=[rand(1)*npu], and the second component is nc₁=nc₀;
at step 754, it is determined whether nc₁=nc₀ is present: if yes, step 755 is performed, and if not, step 756 is performed;
at step 755, nc₁=[rand(1)*npu] and return to step 754;
at step 756, pu₁(nc₁)=pu₀(nc₀) and pu₁(nc₀)=pu₀(nc₁) are updated; and cc₀=cc₀+1 is updated;
step 752 is repeated;
at step 76, the chromosome obtained by mutation operation is decoded and the corresponding placement path length is calculated: if it is superior to the result prior to mutation operation, it is substituted into the chromosome population, which comprises the following specific operations;
at step 761, with u=u₀ as input, step 4 is performed to generate an output containing the corresponding placement path optimization result and the placement path length DT, and D₂=DT is assigned;
at step 762, it is determined whether D₂<D(w₀) is present; if yes, the chromosome population U{w₀}=u₀ is updated, and D(w₀)=D₂ is updated; if not, no processing is performed; im=im+1 is updated and step 54 is repeated.

9. The placement path optimization method of claim 8, wherein the specific process of outputting the optimal placement path optimization result in step 8 comprises the following steps:
at step 81, based on the optimal solution index wb, the optimal chromosome u=U{wb} is obtained;
at step 82, with u as input, step 4 is performed to generate an output containing the optimal placement path optimization result; the optimal placement point distribution result is PAb=PA and the optimal placement sequence result is PSb=PS;
at step 83, the surface mount machine performs mount production based on the optimal placement path optimization result.
